(19) United States
(12) Patent Application Publication
(10) Pub. No.: US 2025/0220970 A1
(43) Pub. Date: Jul. 3, 2025

(54) CHANNEL FORMATION IN GATE-ALL-AROUND COMPLEMENTARY METAL-OXIDE-SEMICONDUCTOR DEVICES

(71) Applicant: Taiwan Semiconductor Manufacturing Company, Ltd., Hsin-Chu (TW)

(72) Inventor: Jhon Jhy Liaw, Hsinchu County (TW)

(21) Appl. No.: 18/619,900

(22) Filed: Mar. 28, 2024

Related U.S. Application Data
(60) Provisional application No. 63/615,222, filed on Dec. 27, 2023.

(51) Int. Cl. H01L 29/423; H01L 21/324; H01L 21/8238; H01L 27/092; H01L 29/06; H01L 29/66; H01L 29/775; H01L 29/786

(52) U.S. Cl. CPC H10D 30/6735; H01L 21/324; H10D 30/014; H10D 30/43; H10D 30/6757; H10D 62/118; H10D 64/017; H10D 84/0167; H10D 84/0172; H10D 84/038; H10D 84/85

(57) ABSTRACT

A method of forming a semiconductor device includes forming a first fin in a first region and a second fin in a second region, forming first suspended nanostructures in the first fin and second suspended nanostructures in the second fin, forming a third semiconductor layer wrapping around each of the second suspended nanostructures in the second fin, performing an anneal process to incorporate materials contained in the third semiconductor layer into the second suspended nanostructures in the second fin, such that a thickness of the second suspended nanostructures is increased to be larger than a thickness of the first suspended nanostructures, and forming a gate stack wrapping around each of the first and second suspended nanostructures.

### PRIORITY

This application claims priority to U.S. Provisional Patent Application Ser. No. 63/615,222 filed Dec. 27, 2023, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

For example, multi-gate devices have been introduced by increasing gate-channel coupling as an effort to improve gate control, reduce off-state current, and reduce short-channel effects (SCEs). One such multi-gate device is gate-all-around (GAA) transistor, in which vertically stacked semiconductor nanostructures serve as channel layers within a channel region of the GAA transistor, and a gate structure wraps around each of the semiconductor nanostructures providing access to the channel region on all four sides. GAA transistors are compatible with conventional complementary metal-oxide-semiconductor (CMOS) processes, allowing them to be aggressively scaled down while maintaining gate control and mitigating SCEs. In the context of CMOS devices, n-type channel region and p-type channel region share one gate structure. Semiconductor nanostructures in the n-type channel region and semiconductor nanostructures in the p-type channel region generally have the same material composition (e.g., silicon) and the same thickness. However, an n-type GAA transistor generally benefits from having thinner semiconductor nanostructures for improving short channel control, and a p-type GAA transistor generally benefits from having thicker semiconductor nanostructures for improving hole mobility. Accordingly, although existing CMOS processes have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is emphasized that, according to the standard practice in the industry, various features are not drawn to scale. In fact, the dimensions of the various features may be arbitrarily increased or reduced for clarity of discussion.

FIG. 1 illustrates a flowchart of an example method for making a semiconductor device, in accordance with some embodiments of the present disclosure.

FIGS. 2, 3, 4, and 5 illustrate cross-sectional views of an exemplary semiconductor device, in accordance with some embodiments of the present disclosure.

FIG. 6 illustrates a perspective view of an exemplary semiconductor device, in accordance with some embodiments of the present disclosure.

FIGS. 7, 8, 9, 10, 11, 12, 13, 14, 15, 16, 17, 18, 19, 20, 21, 22, 23, 24, 26, 27, 28, 29, 30, and 31 illustrate cross-sectional views of an exemplary semiconductor device at intermediate stages of an embodiment of the method of FIG. 1, in accordance with some embodiments of the present disclosure.

FIGS. 25A and 25B illustrate exemplary concentration profiles in p-type channel layers of a semiconductor device, in accordance with some embodiments of the present disclosure.

FIG. 32 illustrates a top view of an exemplary semiconductor device at the conclusion of an embodiment of the method of FIG. 1, in accordance with some embodiments of the present disclosure.

FIG. 33 illustrates a layout of a memory macro that implements the exemplary semiconductor device as shown in FIG. 32, in accordance with some embodiments of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for simplicity and clarity and does not in itself dictate a relationship between the various embodiments and/or configurations discussed.

Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc., as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The present disclosure is generally related to semiconductor devices and fabrication methods thereof, and more particularly to channel formation in n-type and p-type gate-all-around (GAA) transistors in a complementary metal-oxide-semiconductor (CMOS) device.

A GAA transistor includes any device that has its gate structure, or portion thereof, formed on four sides of a channel region (e.g., wrapping around channel layers in a channel region). GAA transistors may be used to realize n-type and p-type transistors located close to each other and shared with the same gate structure, which is often called dual transistors in a CMOS context. The channel region of an n-type GAA transistor with channel layers in the form of vertically stacked semiconductor nanostructures (or simply as nanostructures) and its counterpart in a p-type GAA transistor are also referred to as dual channel regions. The vertically stacked nanostructures may be in the form of nanosheets, nanowires, bars, and/or other suitable configurations. Presented herein are embodiments of devices that may have one or more channel layers (e.g., nanosheets) associated with a single, contiguous gate structure. However, one of ordinary skill would recognize that the teaching can apply to a single channel layer or any number of channel layers. One of ordinary skill may recognize other examples of semiconductor devices that may benefit from aspects of the present disclosure, such as semiconductor devices other than CMOS devices.

In an n-type GAA transistor, a thinner channel layer and accordingly a smaller thickness of the nanostructure (or sheet thickness if the nanostructure in the form of a nanosheet) generally benefit the n-type transistor in achieving better short channel control. In a p-type GAA transistor, a thicker channel layer and accordingly a larger thickness of the nanostructure generally benefits the p-type transistor in achieving better hole mobility. Further, having different semiconductor materials for forming the nanostructures in the n-type and p-type transistors allows individually optimizing performances of the transistors in opposite conductivity types. However, existing semiconductor manufacturing processes generally lead to nanostructures in dual channel regions of a CMOS device having the same material composition (e.g., silicon) and the same thickness.

The present disclosure addresses the above issues by providing improved channel formation methods in forming dual channel regions in a CMOS device. According to some embodiments, after growing a stack of alternating first semiconductor layers (e.g., silicon germanium) and second semiconductor layers (e.g., silicon), a method directly patterns the stack to create first and second fins, and then removes the first semiconductor layers to create suspended nanostructures (e.g., nanowires or nanosheets) in the dual channel regions. The method wraps the suspended nanostructures in the p-type transistor with a thin semiconductor layer (e.g., silicon germanium) and then performs an anneal process to drive germanium into the suspended nanostructures in the p-type transistor. In an example, germanium atoms are driven from a silicon germanium layer into nanostructures made of silicon. Thus, the exemplary method converts the channel layers in the p-type transistor to a semiconductor compound different from the ones in the n-type transistor with a larger sheet thickness. As a result, dual channel regions can be optimized for both n-type and p-type transistors in a simplified fabrication process.

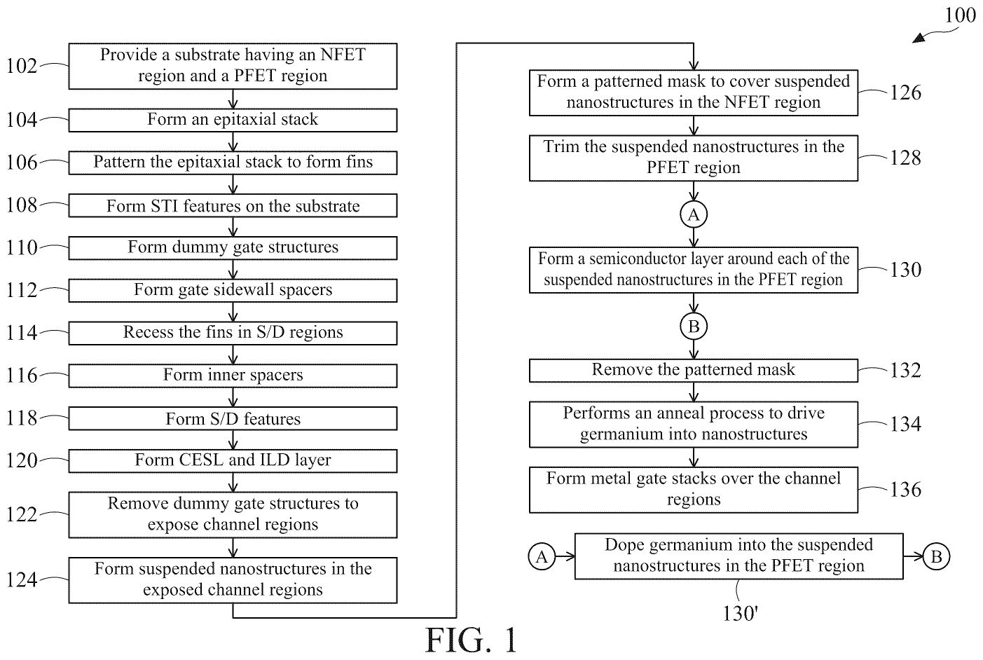

FIG. 1 is a flowchart of a method 100 of forming a semiconductor device structure 200 (or device 200), according to various aspects of the present disclosure. The method 100 is merely an example and is not intended to limit the present disclosure beyond what is explicitly recited in the claims. Additional operations can be provided before, during, and after the method 100, and some operations described can be replaced, eliminated, or moved around for additional embodiments of the method. As with the exemplary devices and methods discussed herein, it is understood that parts of the device 200 may be fabricated by a CMOS technology process flow, and thus some processes are only briefly described herein. Further, the exemplary devices may include various other devices and features, such as other types of devices such as additional transistors, bipolar junction transistors, resistors, capacitors, inductors, diodes, fuses, static random-access memory (SRAM) and/or other logic circuits, etc., but is simplified for a better understanding of the inventive concepts of the present disclosure.

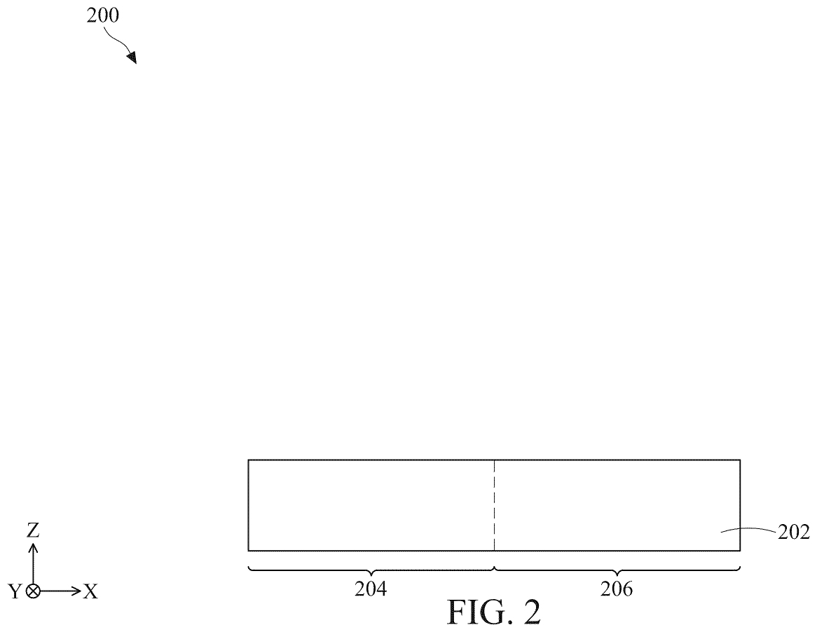

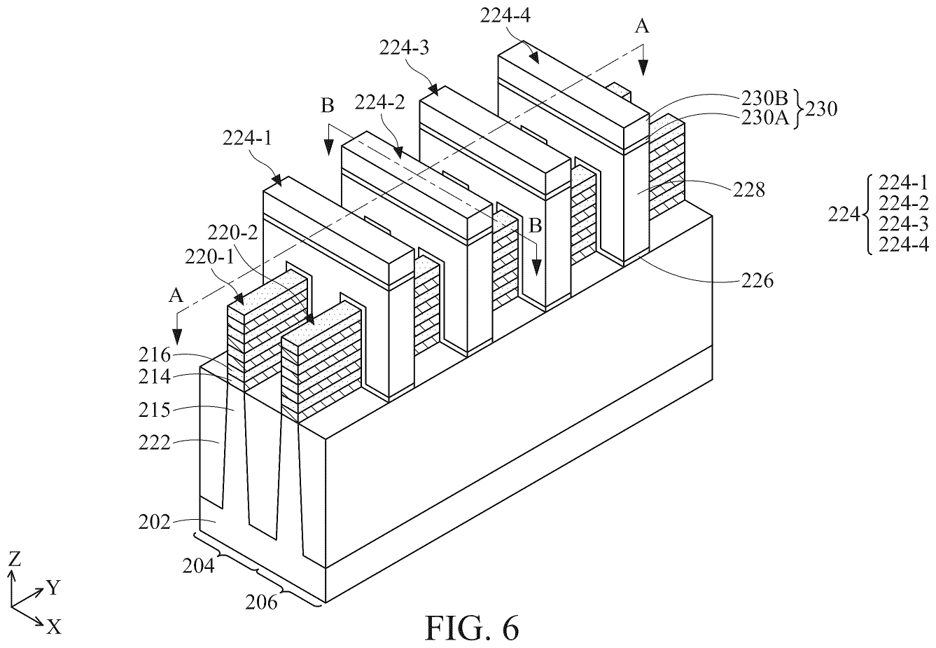

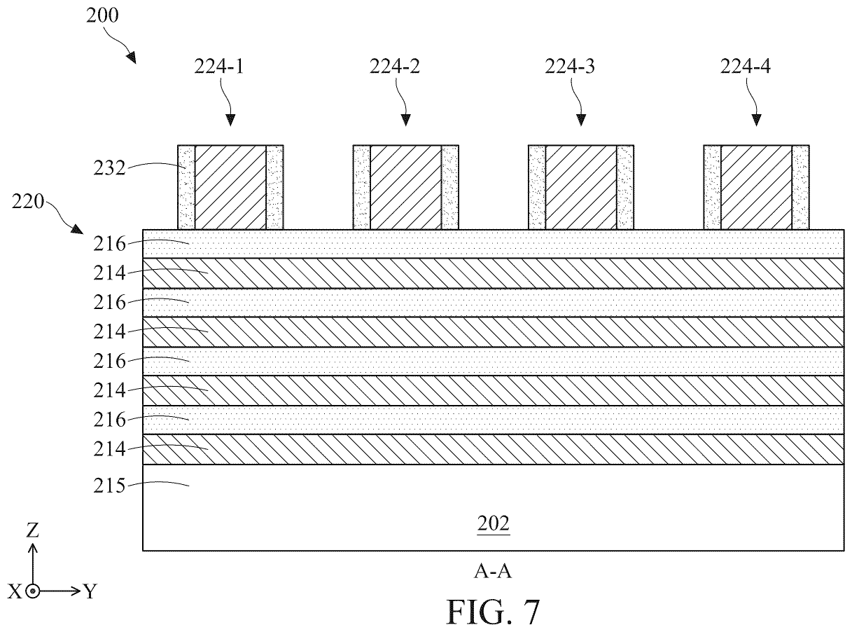

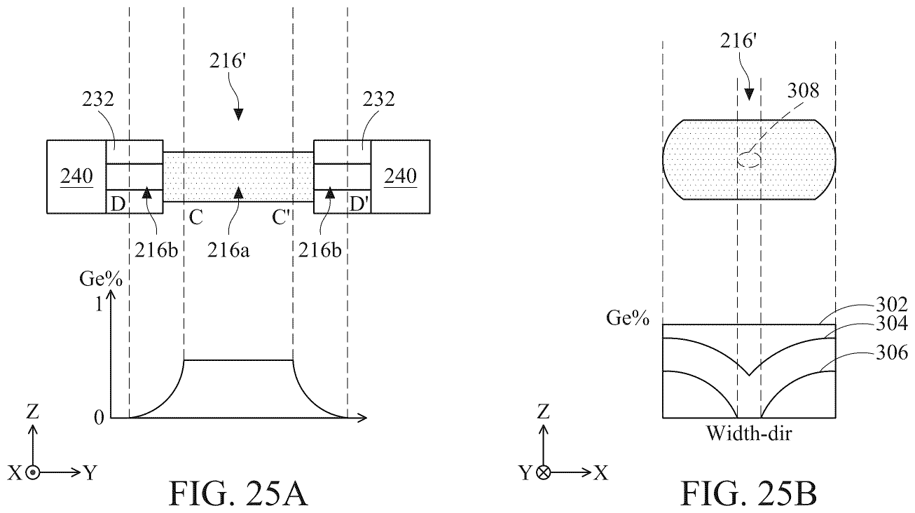

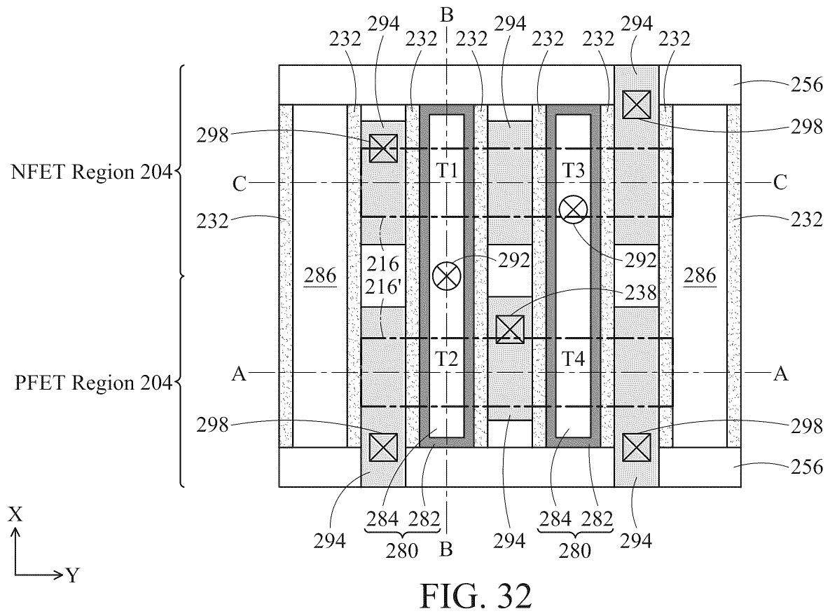

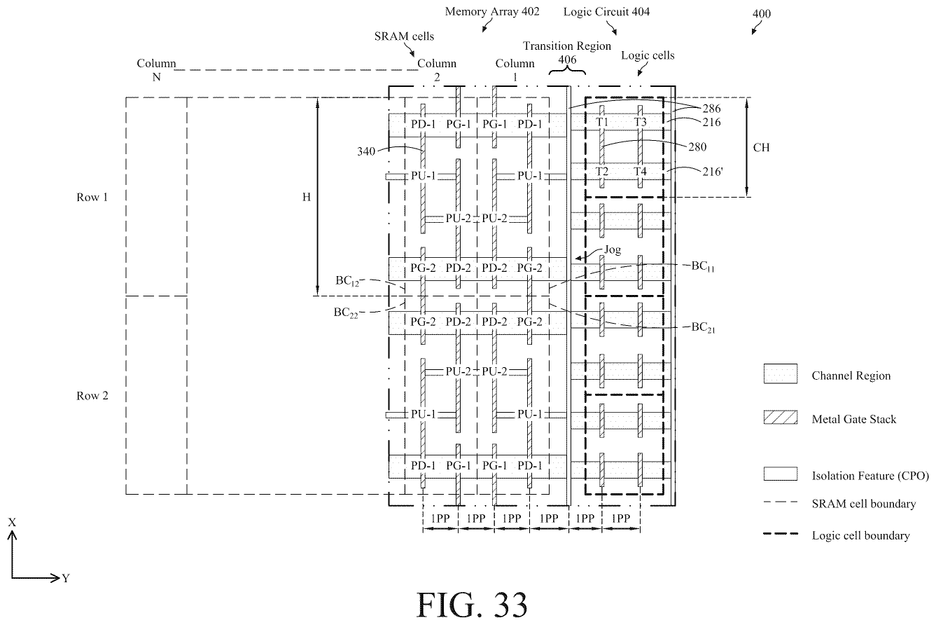

FIG. 1 will be described below in conjunction with FIGS. 2-33. It is noted that the process steps of method 100, including any descriptions given with reference to FIGS. 2-33, as with the remainder of the method and exemplary figures provided in this disclosure, are merely exemplary and are not intended to be limiting beyond what is specifically recited in the claims that follow. FIGS. 2-5 are cross-sectional views of the device 200 at various stages of fabrication according to the method 100. FIG. 6 is a perspective view of the device 200 at an intermediate stage of fabrication according to the method 100. FIGS. 7-24 and 26-31 are cross-sectional views of the device 200 in FIG. 6 (also as in FIG. 32) at various other stages of fabrication according to the method 100. FIGS. 25A and 25B illustrate exemplary germanium concentration profiles in p-type channel layers of the device 200. FIG. 32 is a top view of the device 200 at the conclusion of the method 100. FIG. 33 illustrates the implementation of the device 200 as a portion of a memory macro.

At operation 102, the method 100 (FIG. 1) provides a substrate 202, as shown in FIG. 2. In some embodiments, the substrate 202 may be a semiconductor substrate such as a silicon (Si) substrate. In some embodiments, the substrate 202 includes a single crystalline semiconductor layer on at least its surface portion. The substrate 202 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 202 may include a compound semiconductor and/or an alloy semiconductor. The substrate 202 may include various layers, including conductive or insulating layers formed on a semiconductor substrate. The substrate 202 is separated into regions 204 and 206 by an imaginary dotted line in FIG. 2. In some embodiments, two or more transistors are formed in and/or over the regions 204 and 206 of the substrate 202. In some embodiments, an n-type field effect transistors (NFET) and a p-type field effect transistors (PFET) will be formed in and/or over the regions 204 and 206, respectively. Thus, the region 204 is also referred to as the NFET region 204 and the region 206 is also referred to as the PFET region 206 in the present disclosure. The regions 204 and 206 may include various doping configurations depending on design requirements as is known in the art. For example, different doping profiles (e.g., a p-well in the region 204 and an n-well in the region 206) may be formed in the respective regions designed for different device types (e.g., NFETs or PFETs). The suitable doping may include ion implantation of dopants and/or diffusion processes, such as boron (B) for forming a p-well in the region 204 and phosphorous (P) for forming an n-well in the region 206.

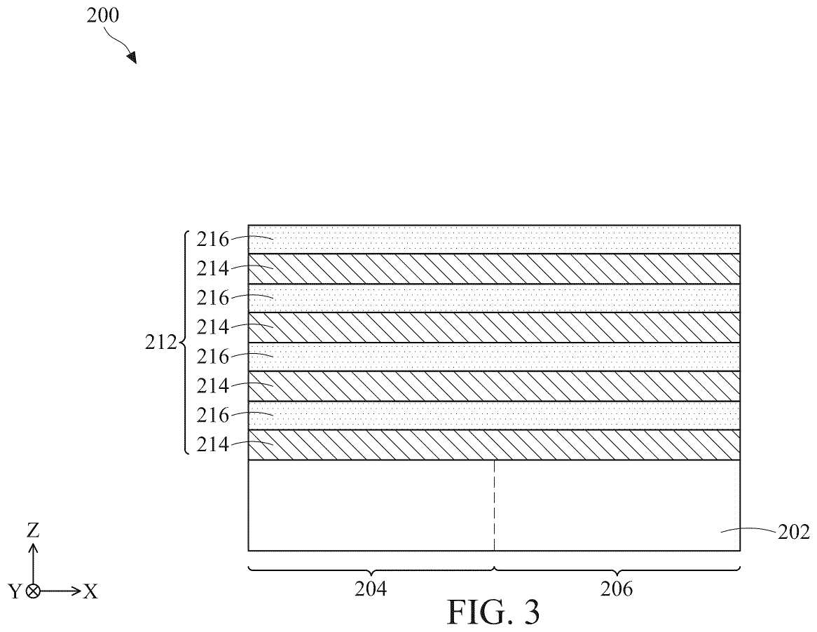

At operation 104, the method 100 (FIG. 1) forms one or more epitaxial layers over the substrate 202, as shown in FIG. 3. In some embodiments, an epitaxial stack 212 is formed over the regions 204 and 206. The epitaxial stack 212 includes epitaxial layers 214 of a first composition interposed by epitaxial layers 216 of a second composition. The first and second composition can be different. In an embodiment, the epitaxial layers 214 are SiGe and the epitaxial layers 216 are silicon. However, other embodiments are possible including those that provide for a first composition and a second composition having different oxidation rates and/or etch selectivity. In some embodiments, the epitaxial layer 214 includes SiGe and where the epitaxial layer 216 includes silicon, the silicon oxidation rate is less than the SiGe oxidation rate. It is noted that four (4) layers of each of epitaxial layers 214 and 216 are illustrated in FIG. 3, which is for illustrative purposes only and not intended to be limiting beyond what is specifically recited in the claims. It can be appreciated that any number of epitaxial layers can be formed in the epitaxial stack 212; the number of layers depending on the desired number of channel layers for the device 200. In some embodiments, the number of epitaxial layers 216 is between 2 and 10, such as 3 or 4.

In some embodiments, the epitaxial layer 214 has a thickness ranging from about 4.5 nm to about 15 nm. The epitaxial layers 214 may be substantially uniform in thickness. In some embodiments, the epitaxial layer 216 has a thickness ranging from about 3 nm to about 8 nm. In some embodiments, the epitaxial layers 216 of the stack are substantially uniform in thickness. As described in more detail below, the epitaxial layer 216 may serve as channel layer(s) for a subsequently-formed GAA transistor and its thickness is chosen based on device performance considerations. The epitaxial layer 214 may serve to reserve a spacing (or referred to as a gap) between adjacent channel layers for a subsequently-formed GAA transistor and its thickness is chosen based on device performance considerations.

By way of example, epitaxial growth of the epitaxial stack 212 may be performed by a molecular beam epitaxy (MBE) process, a metalorganic chemical vapor deposition (MOCVD) process, and/or other suitable epitaxial growth processes. In some embodiments, the epitaxially grown layers, such as the epitaxial layers 216, include the same material as the substrate 202, such as silicon (Si). In some embodiments, the epitaxially grown layers 214 and 216 include a different material than the substrate 202. As stated above, in at least some examples, the epitaxial layer 214 includes an epitaxially grown Si₁₋ₓGeₓ layer (e.g., x is about 25˜55%) and the epitaxial layer 216 includes an epitaxially grown Si layer. Alternatively, in some embodiments, either of the epitaxial layers 214 and 216 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the epitaxial layers 214 and 216 may be chosen based on providing differing oxidation and etch selectivity properties. In various embodiments, the epitaxial layers 214 and 216 are substantially dopant-free, where for example, no intentional doping is performed during the epitaxial growth process.

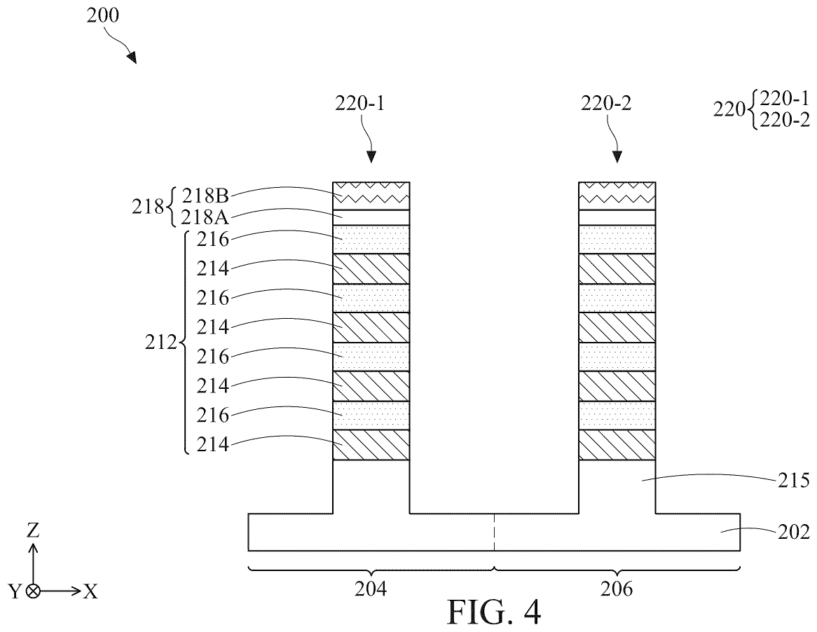

At operation 106, the method 100 (FIG. 1) patterns the epitaxial stack 212 to form fins 220-1 and 220-2 (collectively as fins 220), as shown in FIG. 4. In the illustrated embodiment, a top portion of the substrate 202 is also patterned. In various embodiments, each of the fins 220 includes an upper portion of the interleaved epitaxial layers 214 and 216 and a bottom portion protruding from the substrate 202. The bottom portion protruding from the substrate 202 is also referred to as the fin-shape base 215 or mesa 215. In some embodiments, operation 106 includes forming a mask layer 218 over the epitaxial stack 212. The mask layer 218 includes a first mask layer 218A and a second mask layer 218B. In some embodiments, the first mask layer 218A is a pad oxide layer made of a silicon oxide, which can be formed by a thermal oxidation; the second mask layer 218B is made of a silicon nitride (SiN), which is formed by chemical vapor deposition (CVD), including low pressure CVD (LPCVD) and plasma enhanced CVD (PECVD), physical vapor deposition (PVD), atomic layer deposition (ALD), or other suitable process. The mask layer 218 is patterned into a mask pattern by using patterning operations including photo-lithography and etching.

In some embodiments, operation 106 patterns the epitaxial stack 212 using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the epitaxial stack 212 in an etching process, such as a dry etch (e.g., reactive ion etching), a wet etch, and/or other suitable process, through openings defined in the patterned mask layer 218. The stacked epitaxial layers 214 and 216 are thereby patterned into fins 220 with trenches between adjacent fins. Each of the fins 220 protrudes upwardly in the z-direction from the substrate 202 and extends lengthwise in the y-direction. In FIG. 4, two (2) fins 220 are spaced apart along the x-direction with one fin disposed above the NFET region 204 and one fin disposed above the PFET region 206. But the number of the fins is not limited to two, and may be as small as one or more than two.

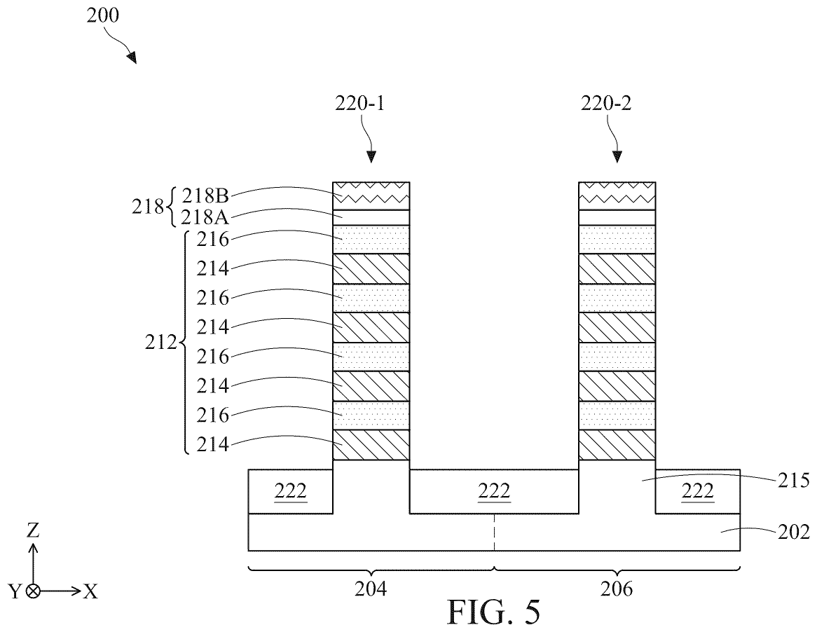

At operation 108, the method 100 (FIG. 1) fills the trenches between adjacent fins 220 with a dielectric material to form an isolation feature 222, as shown in FIG. 5. The isolation feature 222 may include one or more dielectric layers. Suitable dielectric materials for the isolation feature 222 may include silicon oxides, silicon nitrides, silicon carbides, fluorosilicate glass (FSG), low-K dielectric materials, and/or other suitable dielectric materials. The dielectric material may be deposited by any suitable technique including thermal growth, CVD, HDP-CVD, PVD, ALD, and/or spin-on techniques. Method 100 at operation 108 subsequently recesses the isolation features 222 to form shallow trench isolation (STI) features (also denoted as STI features 222). In the illustrated embodiment, the STI features 222 are disposed on sidewalls of the protruding portion of the substrate 202. A top surface of the STI feature 222 may be coplanar with a bottom surface of the epitaxial stack 212 or lower than the bottom surface of the epitaxial stack 212 for about 1 nm to about 10 nm. Any suitable etching technique may be used to recess the isolation features 222 including dry etching, wet etching, RIE, and/or other etching methods, and in an exemplary embodiment, an anisotropic dry etching is used to selectively remove the dielectric material of the isolation features 222 without etching the fins 220. The mask layer 218 may also be removed before, during, and/or after the recessing of the isolation features 222. In some embodiments, the mask layer 218 is removed by a CMP process performed prior to the recessing of the isolation features 222. In some embodiments, the mask layer 218 is removed by an etchant used to recess the isolation features 222.

At operation 110, the method 100 (FIG. 1) forms sacrificial (dummy) gate structures 224-1, 224-2, 224-3, and 224-4 (collectively as sacrificial gate structures 224), as shown in FIG. 6. It can be appreciated that any number of sacrificial gate structures can be formed at operation 110. Each of the sacrificial gate structure 224 is formed over portions of the fins 220 which are to be channel regions. The sacrificial gate structures 224 define the channel regions of the GAA transistors. The sacrificial gate structure 224 includes a sacrificial gate dielectric layer 226 and a sacrificial gate electrode layer 228. The sacrificial gate structures 224 are formed by first blanket depositing the sacrificial gate dielectric layer 226 over the fins 220. A sacrificial gate electrode layer 228 is then blanket deposited on the sacrificial gate dielectric layer 226 and over the fins 220. The sacrificial gate electrode layer 228 includes silicon such as polycrystalline silicon or amorphous silicon. The thickness of the sacrificial gate dielectric layer is in a range from about 1 nm to about 5 nm in some embodiments. The thickness of the sacrificial gate electrode layer is in a range from about 100 nm to about 200 nm in some embodiments. In some embodiments, the sacrificial gate electrode layer is subjected to a planarization operation. The sacrificial gate dielectric layer 226 and the sacrificial gate electrode layer 228 are deposited using CVD, including LPCVD and PECVD, PVD, ALD, or other suitable process. Subsequently, a mask layer 230 is formed over the sacrificial gate electrode layer. The mask layer 230 may include a pad silicon oxide layer 230A and a silicon nitride mask layer 230B. Subsequently, a patterning operation is performed on the mask layer 230 and sacrificial gate dielectric and electrode layers are patterned into the sacrificial gate structures 224. By patterning the sacrificial gate structures 224, the fins 220 are partially exposed on opposite sides of each of the sacrificial gate structures 224, thereby defining source/drain (S/D) regions. In this disclosure, source/drain region(s) may refer to a source or a drain, individually or collectively dependent upon the context.”

At operation 112, the method 100 (FIG. 1) forms gate sidewall spacers 232 on sidewalls of the sacrificial gate structures 224, as shown in FIG. 7 which is a cross-sectional view along the lengthwise direction of one of the fins 220 (A-A line) in FIG. 6. The cross-sectional view along the lengthwise direction of another fin 220 is similar to what is illustrated in FIG. 7 and omitted herein for the sake of simplicity. The gate sidewall spacers 232 also cover a portion of the top surfaces of the fin 220. The gate sidewall spacers 232 may include a dielectric material such as silicon oxide, silicon nitride, silicon carbide, silicon oxynitride, SiCN films, silicon oxycarbide, SiOCN films, and/or combinations thereof. In some embodiments, the gate sidewall spacers 232 include multiple layers, such as main spacer walls, liner layers, and the like. By way of example, the gate sidewall spacers 232 may be formed by depositing a dielectric material layer over the sacrificial gate structure 224 using processes such as, a CVD process, a subatmospheric CVD (SACVD) process, a flowable CVD process, an ALD process, a PVD process, or other suitable process. In some embodiments, the deposition of the dielectric material layer is followed by an etching-back (e.g., anisotropically) process to expose portions of the fin 220 adjacent to and not covered by the sacrificial gate structure 224 (e.g., S/D regions). The dielectric material layer may remain on the sidewalls of the sacrificial gate structure 224 as gate sidewall spacers 232. In some embodiments, the etching-back process may include a wet etch process, a dry etch process, a multiple-step etch process, and/or a combination thereof. The gate sidewall spacers 232 may have a thickness ranging from about 5 nm to about 20 nm.

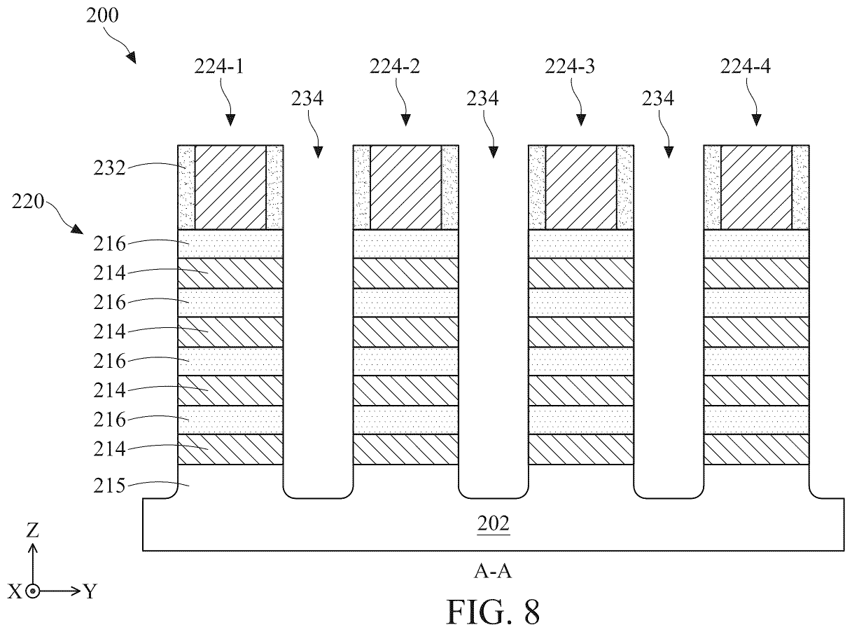

At operation 114, the method 100 (FIG. 1A) recesses portions of the fins 220 to form recesses 234 in the S/D regions, as shown in FIG. 8 which is a cross-sectional view along A-A line of the device 200 in FIG. 6. The stacked epitaxial layers 214 and 216 are etched down at the S/D regions. In the illustrated embodiment, a top portion of the substrate 202 is also etched. In some embodiments, method 100 at operation 114 forms the recesses 234 by a suitable etching process, such as a dry etching process, a wet etching process, or an RIE process. The etching process at operation 118 may implement a dry etching process using an etchant including a bromine-containing gas (e.g., HBr and/or CHBR₃), a fluorine-containing gas (e.g., CF₄, SF₆, CH₂F₂, CHF₃, and/or C₂F₆), other suitable gases, or combinations thereof.

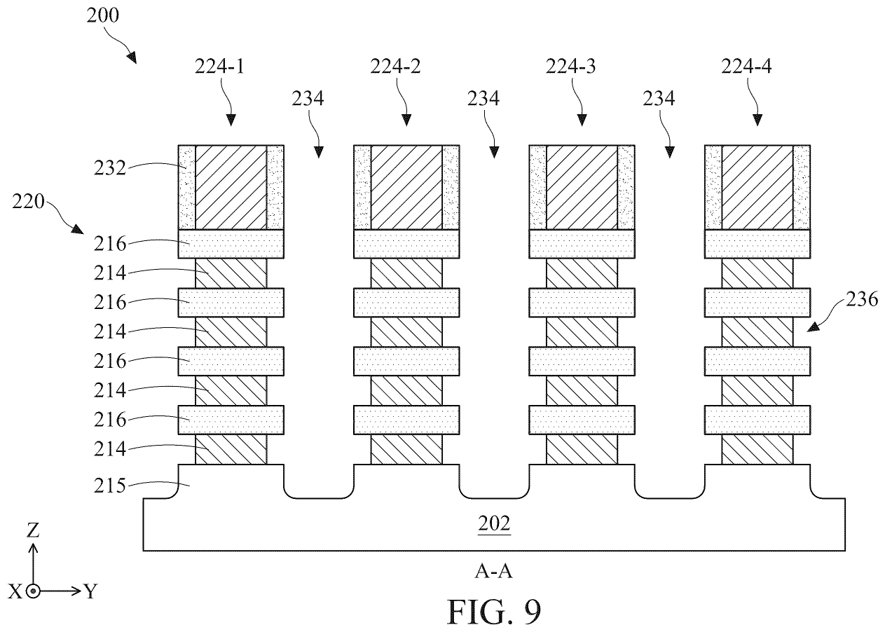

At operation 116, the method 100 (FIG. 1) forms inner spacers directly under the gate sidewall spacers 232. In some embodiments, operation 116 first laterally etches the epitaxial layers 214 in the y-direction, thereby forming cavities 236, as shown in FIG. 9 which is a cross-sectional view along A-A line of the device 200 in FIG. 6. The amount of etching of the epitaxial layers 214 is in a range from about 1 nm to about 4 nm in some embodiments. The epitaxial layers 214 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. Alternatively, method 100 at operation 120 may first selectively oxidize lateral ends of the epitaxial layers 214 that are exposed in the recesses 234 to increase the etch selectivity between the epitaxial layers 214 and 216. In some examples, the oxidation process may be performed by exposing the device 200 to a wet oxidation process, a dry oxidation process, or a combination thereof.

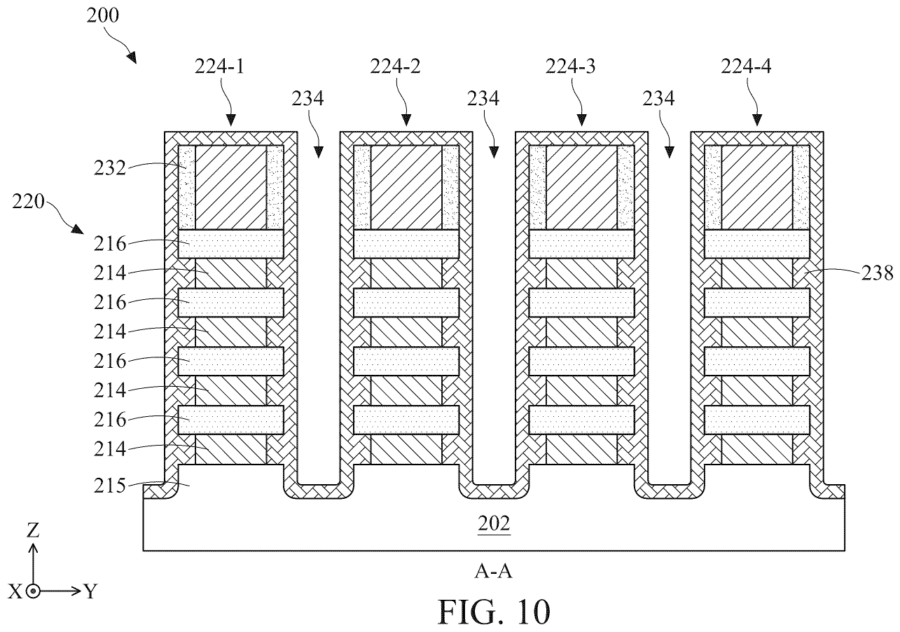

Subsequently, method 100 at operation 116 forms an inner spacer material layer 238 on the lateral ends of the epitaxial layer 214 and on the epitaxial layers 216 in the recesses 234 and cavities 236, as shown in FIG. 10 which is a cross-sectional view along A-A line of the device 200 in FIG. 6. The inner spacer material layer 238 may include silicon oxides, silicon nitrides, silicon carbides, silicon carbide nitride, silicon oxide carbide, silicon carbide oxynitride, and/or other suitable dielectric materials. In some embodiments, the inner spacer material layer 238 is deposited as a conformal layer. The inner spacer material layer 238 can be formed by ALD or any other suitable method. By conformally forming the inner spacer material layer 238, the size of the cavity 236 is reduced or completely filled.

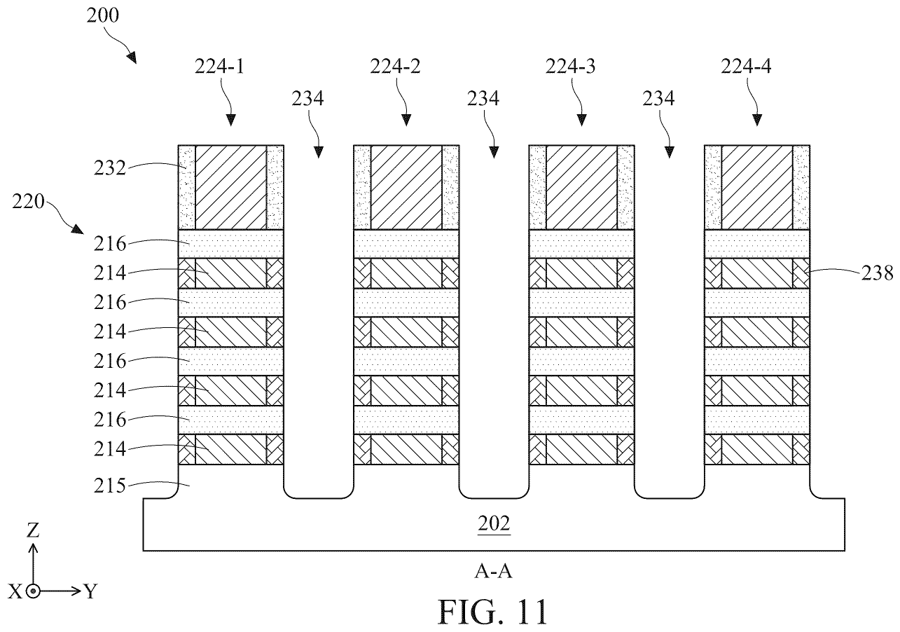

After the inner spacer material layer 238 is formed, an etching operation is performed to partially remove the inner spacer material layer 238, as shown in FIG. 11 which is a cross-sectional view along A-A line of the device 200 in FIG. 6. By this etching, the inner spacer material layer 238 remains substantially within the cavity 236, because of a small volume of the cavity. Generally, plasma dray etching etches a layer in wide and flat areas faster than a layer in concave (e.g., holes, grooves and/or slits) portions. Thus, the inner spacer material layer 238 can remain inside the cavities 236. The remained portions of the inner spacer material layer 238 is denoted as the inner spacers 238.

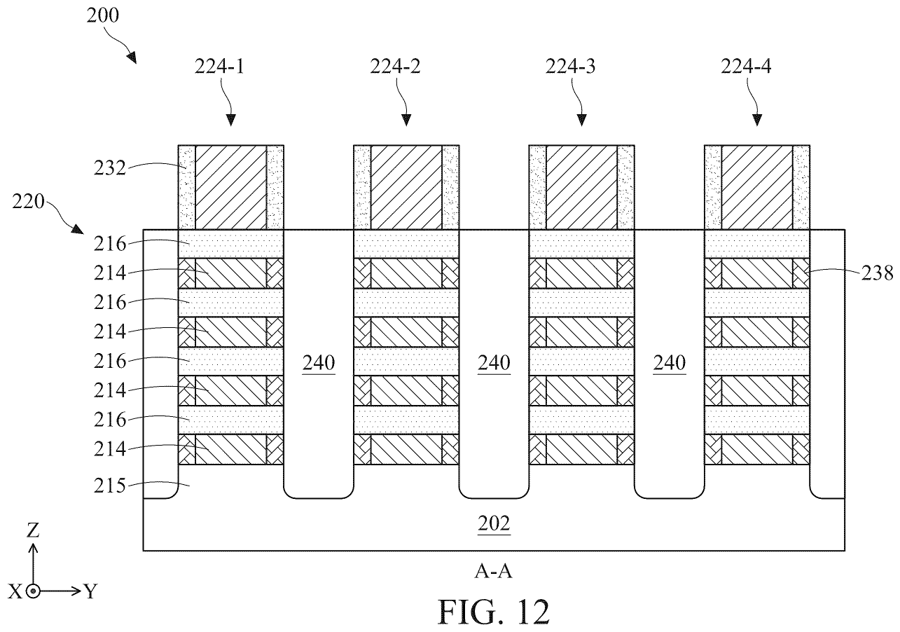

At operation 118, the method 100 (FIG. 1) forms epitaxial S/D features 240 in recesses 234, as shown in FIG. 12 which is a cross-sectional view along A-A line of the device 200 in FIG. 6. In some embodiments, the epitaxial S/D features 240 for NFETs may include silicon, and the epitaxial S/D features 240 for PFETs may include SiGe. In some embodiments, the epitaxial S/D features 240 for NFETs and PFETs may both include silicon. The epitaxial S/D features 240 for NFETs may be doped with dopants such as arsenic (As) or phosphorus (P), and the epitaxial S/D features 240 for PFETs may be doped with dopants such as germanium (Ge) or boron (B). In some embodiments, the epitaxial S/D features 240 are formed by an epitaxial growth method using vapor-phase epitaxy (VPE), CVD, ALD, or molecular beam epitaxy (MBE). The epitaxial S/D features 240 are formed in contact with the epitaxial layers 216, and separated from the epitaxial layers 214 by the inner spacers 238. In some embodiment, cavities 236 are not filled by the inner spacer material 238 but be capped by the epitaxial S/D features 240. Therefore, capped cavities 236 are also referred to as “air spacers”.

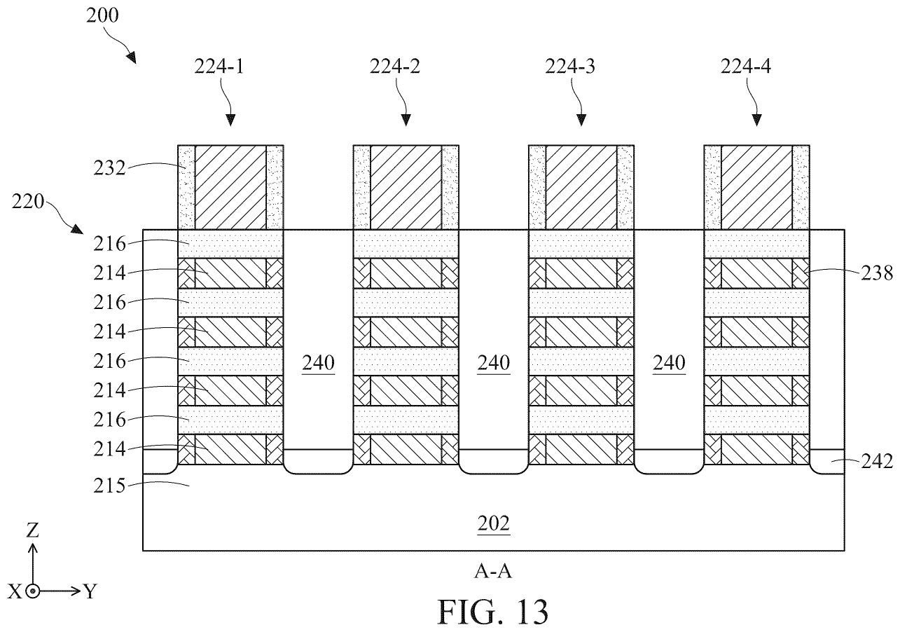

FIG. 13 illustrates an alternative resultant structure at the conclusion of operation 118, which is a cross-sectional view along A-A line of the device 200 in FIG. 6. Many aspects of the device 200 as depicted in FIGS. 12 and 13 are the same. One difference is that a dielectric film 242 is deposited in the bottom of the recesses 234 and above the substrate 202. In some embodiments, the dielectric film 242 may include a metal oxide or a metal nitride, such as La₂O₃, Al₂O₃, ZnO, ZrN, Zr₂Al₃O₉, TiO₂, TaO₂, ZrO₂, HfO₂, Y₂O₃, AlON, TaCN, other suitable material(s), or combinations thereof. In some embodiments, the dielectric film 242 may include silicon oxide, silicon oxycarbonitride, silicon nitride, silicon oxynitride, silicon oxycarbide, carbon-rich silicon carbonitride, or a low-k dielectric material. The dielectric film 242 is selected such that it has a different etch selectivity from the inner spacers 238, allowing the dielectric film 242 to be formed by a directional deposition and etch back process without causing etching loss to the inner spacers 238. The dielectric film 242 may include a single layer or multiple layers. In some embodiments, the dielectric film 242 has a thickness in a range of about 1 nm to about 30 nm. The dielectric film 242 partially covers the sidewalls of the bottommost inner spacer 238. The dielectric film 242 separates the epitaxial S/D features 240 from contacting the substrate 202, which improves the suppression of leakage current from the S/D regions into the substrate. In some embodiments, the space reserved by the dielectric film 242 is replaced an “air cavity” instead. The air cavity also separates the epitaxial S/D features 240 from contacting the substrate 202 or at least reduces contact areas between the epitaxial S/D features 240 and the substrate 202, which also improves the suppression of leakage current from the S/D regions into the substrate. In some embodiments, the dielectric film 242 is formed in the recesses 234 in both the NFET region 204 and the PFET region 206. In some embodiments, the dielectric film 242 is only formed in the recesses 234 in the NFET region 204 and not in the PFET region 206. Without forming the dielectric film 242 in the PFET region 206 allows the subsequently formed epitaxial S/D features 240 in the PFET region 206 to extend downward into the substrate 202 and benefit from a better strain performance due to a larger depth and a greater volume than its counterparts in the NFET region 204.

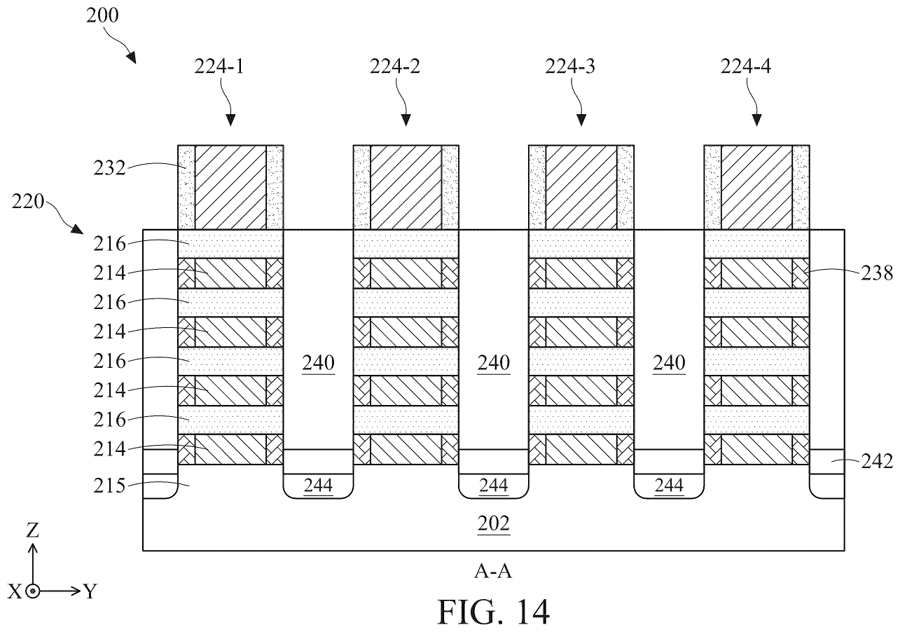

FIG. 14 illustrates an alternative resultant structure at the conclusion of operation 118, which is a cross-sectional view along A-A line of the device 200 in FIG. 6. Many aspects of the device 200 as depicted in FIGS. 14 and 13 are the same. One difference is that a buffer epitaxial layer 244 is deposited in the bottom of the recesses 234 and stacked between the substrate 202 and the subsequently formed dielectric film 242. The buffer epitaxial layer 244 is epitaxially grown from the recesses 234. By way of example, epitaxial growth of the buffer epitaxial layer 244 may be performed by VPE, ultra-high vacuum CVD (UHV-CVD), MBE, and/or other suitable epitaxial grow processes. In some embodiments, the buffer epitaxial layer 244 includes the same material as the substrate 202, such as silicon. In some alternative embodiments, the buffer epitaxial layer 244 includes a different semiconductor material than the silicon substrate 202, such as SiGe, SiSn, or other suitable semiconductor material. In some embodiments, the buffer epitaxial layer 244 is dopant-free, where for example, no intentional doping is performed during the epitaxial growth process. As a comparison, in one instance, the substrate 202 is lightly doped and has a higher doping concentration than the buffer epitaxial layer 244. The buffer epitaxial layer 244 provides a high resistance path from the S/D regions to the semiconductor substrate, such that the leakage current in the semiconductor substrate is suppressed. In some embodiments, the dielectric film 242 disposed above the buffer epitaxial layer 244 has a thickness in a range of about 1 nm to about 30 nm.

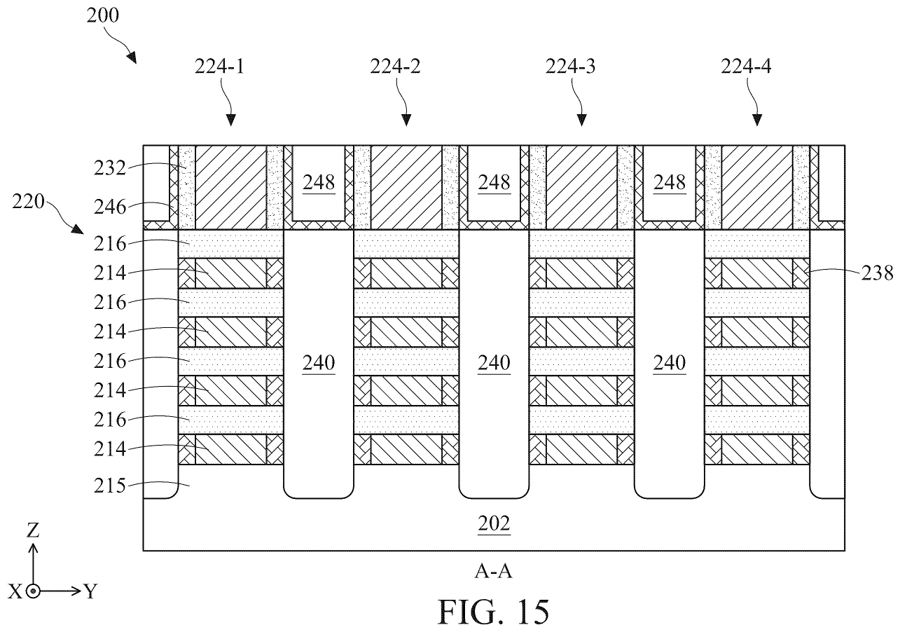

At operation 120, the method 100 (FIG. 1) forms a contact etch stop layer (CESL) 246 over the epitaxial S/D features 240 and an interlayer dielectric (ILD) layer 248 over the CESL layer 246, as shown in FIG. 15 which is a cross-sectional view along A-A line of the device 200 in FIG. 6. It is understood that the various configurations in S/D regions as depicted in FIGS. 12, 13, and 14 are equally applicable during subsequent operations of method 100. For purposes of simplicity and clarity, however, the following operations of the method 100 will be discussed in the context of the embodiment depicted in FIG. 12. The CESL layer 246 may comprise silicon nitride, silicon oxynitride, silicon nitride with oxygen (O) or carbon (C) elements, and/or other materials; and may be formed by CVD, PVD (physical vapor deposition), ALD, or other suitable methods. The ILD layer 248 may comprise tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 248 may be formed by PECVD, flowable CVD (FCVD), or other suitable methods. In some embodiments, forming the ILD layer 248 further includes performing a CMP process to planarize a top surface of the device 200, such that the top surfaces of the sacrificial gate structures 224 are exposed.

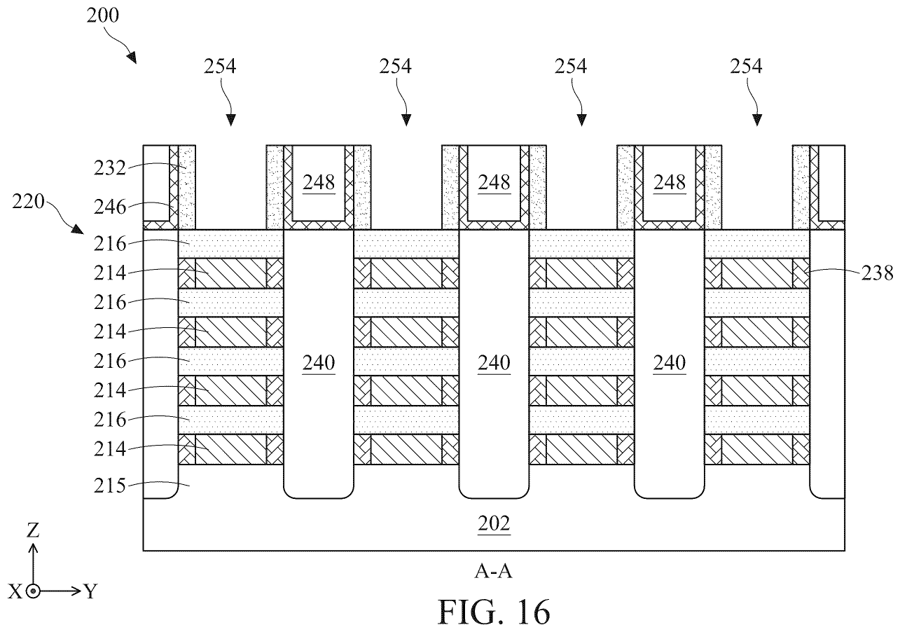

At operation 122, the method 100 (FIG. 1) removes the sacrificial gate structures 224 to form gate trenches 254, as shown in FIG. 16 which is a cross-sectional view along A-A line of the device 200 in FIG. 6. The gate trenches 254 exposes the fins 220 in the channel regions. The ILD layer 248 and the CESL layer 246 protects the epitaxial S/D features 240 during the removal of the sacrificial gate structures 224. The sacrificial gate structures 224 can be removed using plasma dry etching and/or wet etching. When the sacrificial gate electrode layer is polysilicon and the ILD layer 248 is an oxide, a wet etchant such as a TMAH solution can be used to selectively remove the sacrificial gate electrode layer. The sacrificial gate dielectric layer is thereafter removed using plasma dry etching and/or wet etching.

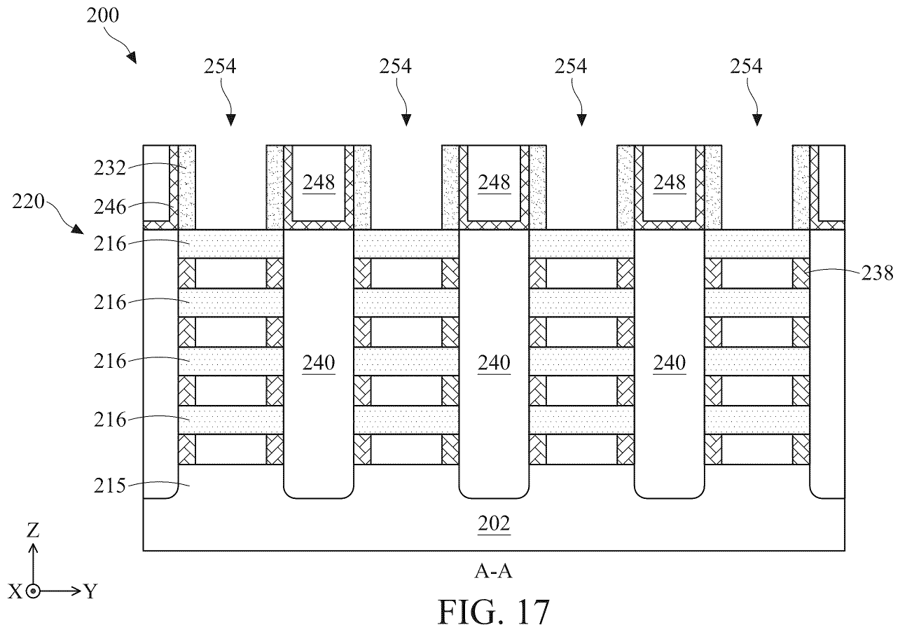

At operation 124, the method 100 (FIG. 1) releases channel layers (or referred to as channel members) from the channel regions of the GAA transistors, as shown in FIG. 17 which is a cross-sectional view along A-A line of the device 200 in FIG. 6. In the illustrated embodiment, channel layers are epitaxial layers 216 in the form of nanostructures, particularly nanosheets in the depicted embodiment. It is understood that the nanostructures may be nanowires, bar-shaped, or in other suitable shapes. In the present embodiment, the epitaxial layers 216 include silicon, and the epitaxial layers 214 include silicon germanium. The plurality of epitaxial layers 214 may be selectively removed. In some implementations, the selectively removal process includes oxidizing the plurality of epitaxial layers 214 using a suitable oxidizer, such as ozone. Thereafter, the oxidized epitaxial layers 214 may be selectively removed from the gate trenches 254. To further this embodiment, the operation 124 includes a dry etching process to selectively remove the epitaxial layers 214, for example, by applying an HCl gas at a temperature of about 500 degrees Celsius to about 700 degrees Celsius, or applying a gas mixture of CF₄, SF₆, and CHF₃. For the sake of simplicity and clarity, after operation 124, the epitaxial layers 216 are denoted as nanostructures 216 or nanosheets 216.

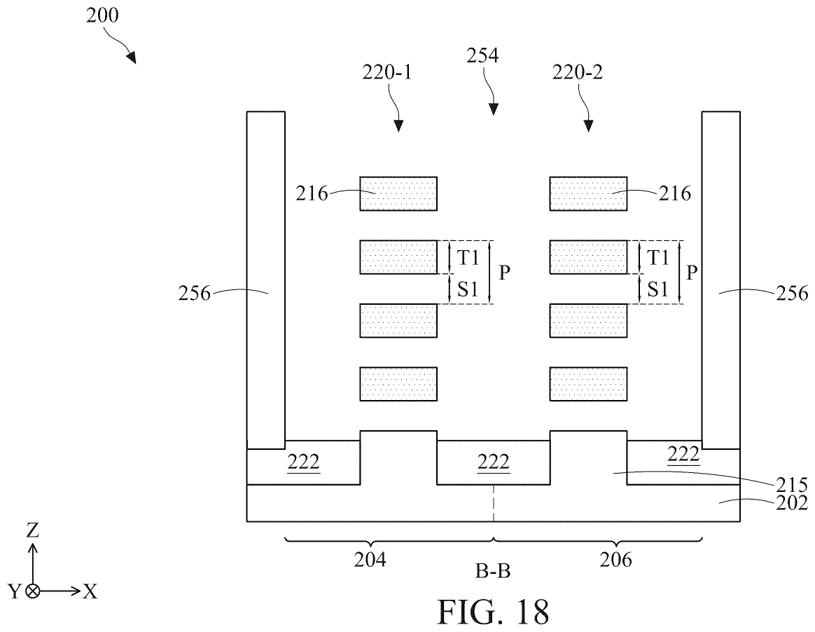

At the conclusion of operation 124, two groups of vertically stacked nanostructures 216 are formed above the regions 204 and 206, respectively, as shown in FIG. 18 which is a cross-sectional view along B-B line of the device 200 in FIG. 6. Along the X-direction, the nanostructures 216 in the fin 220-1 and the nanostructures 216 in the fin 220-2 are sandwiched between two opposing gate end dielectric features 256. The gate end dielectric features 256 may be a multi-layer structure that includes the gate sidewall spacers 232, the CESL layer 246, and the ILD layer 248, in some embodiments. The gate end dielectric features 256 isolate the subsequently formed n-type and p-type GAA transistors as dual transistors in a CMOS device from other adjacent devices. In the present embodiment, the nanostructures 216 in the fin 220-1 above the region 204 are for forming the n-type GAA transistor, and the nanostructures 216 in the fin 220-2 above the region 206 are for forming the p-type GAA transistor. This configuration is for illustrative purposes only and does not limit the present disclosure. In some embodiments, each nanostructure 216 has a channel thickness (denoted as T1) of about 3 to about 8 nm and is spaced apart from adjacent nanosheets for a channel spacing (denoted as S1) of about 4.5 nm to about 15 nm. A vertical channel pitch (denoted as P, as P=T1+S1) is about 8 nm to about 24 nm, in some embodiments.

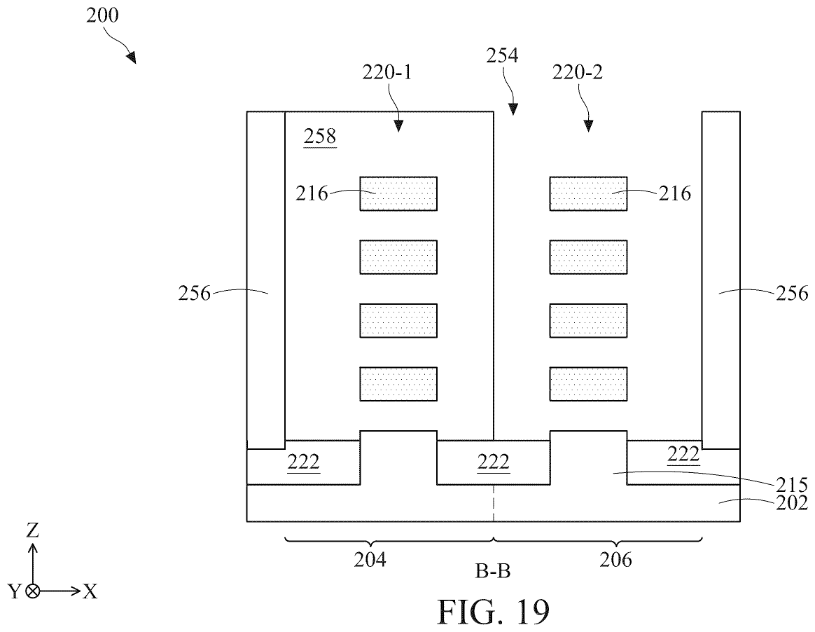

At operation 126, the method 100 (FIG. 1) forms a patterned mask 258 in the gate trenches 254, as shown in FIG. 19 which is a cross-sectional view along B-B line of the device 200 in FIG. 6. The patterned mask 258 covers the nanostructures 216 in the fin 220-1 in the NFET region 204 and includes an opening that exposes the nanostructures 216 in the fin 220-2 in the PFET region 206. In one embodiment, the patterned mask 258 is a soft mask such as a patterned resist layer. In one embodiment, the patterned mask 258 includes a hard mask (instead of a soft mask). In some examples, the hard mask includes silicon oxide, silicon nitride, silicon oxynitride, silicon carbide, silicon carbide nitride, silicon carbide oxynitride, other semiconductor material, and/or other dielectric material. The hard mask may be formed by thermal oxidation, CVD, ALD, or any other appropriate method. The hard mask may be patterned using any suitable methods such as a photolithography process, which may include forming a resist layer on the hard mask, exposing the resist by a lithography exposure process, performing a post-exposure bake process, developing the photoresist layer to form the patterned photoresist layer that exposes part of the hard mask, patterning the hard mask, and finally removing the patterned resist layer. The lithography process may be alternatively replaced by other suitable techniques, such as e-beam writing, ion-beam writing, maskless patterning or molecular printing.

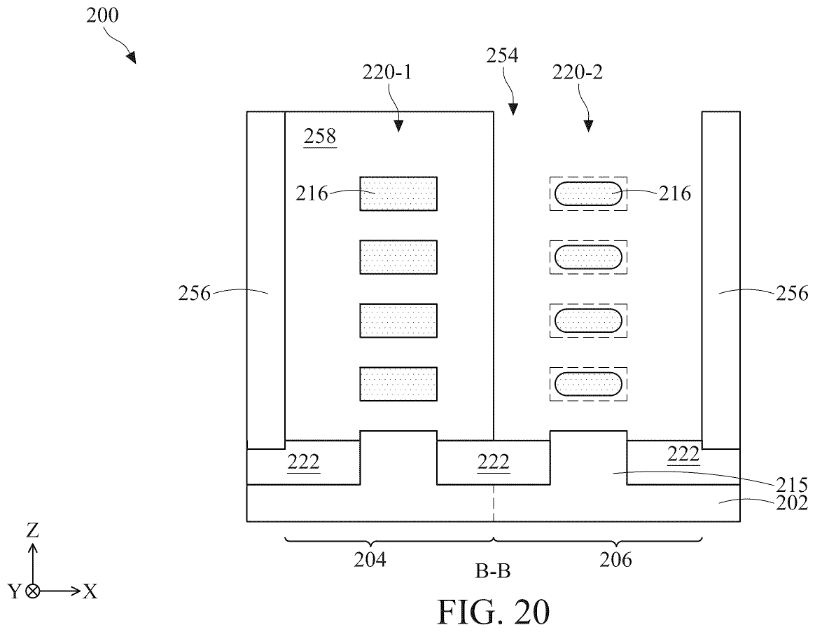

At operation 128, the method 100 (FIG. 1) performs a trimming process to the nanostructures 216 in the fin 220-2, as shown in FIG. 20, which is a cross-sectional view along B-B line of the device 200 in FIG. 6. The rectangular box with dashed lines in FIG. 20 denotes the shape of the nanostructures 216 prior to the trimming process for a comparison. The trimming process is configured to thin down the thickness of the nanostructures 216 to enlarge a channel spacing between adjacent nanostructures 216. The enlarged channel spacing facilitates the depositing of a semiconductor layer to wrap around the nanostructures 216 in the fin 220-2 in the following operations. The trimming process may use any suitable etching process such as dry etching, wet etching, and/or RIE. The trimming process may also reduce a width of the nanostructures 216 in the fin 220-2. Due to the partial etching, the trimmed nanostructures 216 may also have rounded corners other than substantially right corners in the previous rectangle-shape. In some embodiments, operation 128 may be optional, and the method 100 may skip operation 128.

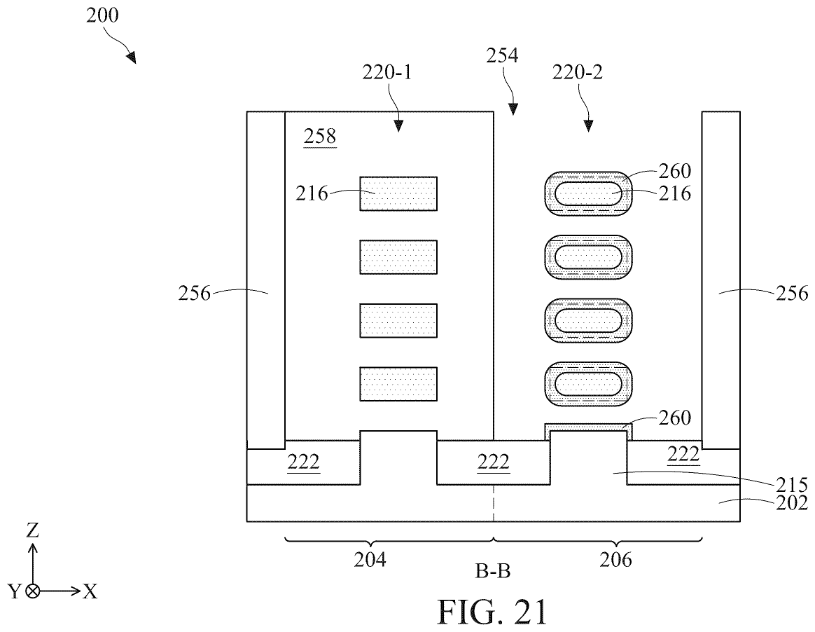

At operation 130, the method 100 forms a semiconductor layer 260 wrapping around each of the nanostructures 216 in the fin 220-2, as shown in FIG. 21, which is a cross-sectional view along B-B line of the device 200 in FIG. 6. Since the semiconductor layer 260 is used to convert the channel region in the PFET region 206 from a first-type (e.g., n-type) to a second-type (e.g., p-type), the semiconductor layer 260 has different compositions from the semiconductor material in the nanostructures 216. In various embodiments, the semiconductor layers 260 has compositions that provide for different oxidation rates and/or different etch selectivity from the semiconductor material in the nanostructures 216. In an embodiment, the semiconductor layer 260 includes silicon germanium (Si₁₋ₓGeₓ), while the nanostructures 216 in the fins 220-1 and 220-2 include silicon (Si). In some embodiments, the semiconductor layer 260 includes Si₁₋ₓGeₓ that includes about 10% to about 100% (0.1≤x≤1) Ge in molar ratio. A sufficient amount of Ge in the semiconductor layer 260 helps converting the channel region in the fin 220-2 from a first-type (e.g., n-type) to a second-type (e.g., p-type). For example, Ge may comprise about 60% to about 80% of Si₁₋ₓGeₓ in molar ratio. Such a range of Ge, combined with subsequent processing steps, effectively converts the channel region in the PFET region 206 from the first-type to the second-type.

In some embodiments, the semiconductor layer 260 is epitaxially grown from the semiconductor surfaces of the nanostructures 216 in the fin 220-2. For example, the semiconductor layer 260 may be grown by VPE, ultra-high vacuum CVD (UHV-CVD), MBE, and/or other suitable epitaxial grow processes. The epitaxial growth approach allows materials in the semiconductor layer 260 to form crystalline lattices that are consistent with those in the nanostructures 216. In some embodiments, the semiconductor layer 260 is a conformal layer that has a substantially uniform thickness. In some embodiments, the semiconductor layer 260 may have a thickness of about 2 to about 5 nm. In some embodiments, a thickness ratio between the surrounded nanostructure 216 and the surrounding semiconductor layer 260 is about 2:1 to about 10:1. In other words, the semiconductor layer 260 is thinner than its corresponding nanostructure 216. Such a thickness ratio provides the suitable amount of germanium needed to convert the channel regions in the PFET region 206 from n-type to p-type. As shown in FIG. 21, the semiconductor layer 260 may also epitaxially grow from the semiconductor surfaces (top and sidewall surfaces) of the fin-shape base 215 in the PFET region 206. Accordingly, the top surface of the fin-shape base 215 in the PFET region 206 may be higher than the top surface of the fin-shape base 215 in the NFET region 204 at the conclusion of operation 132.

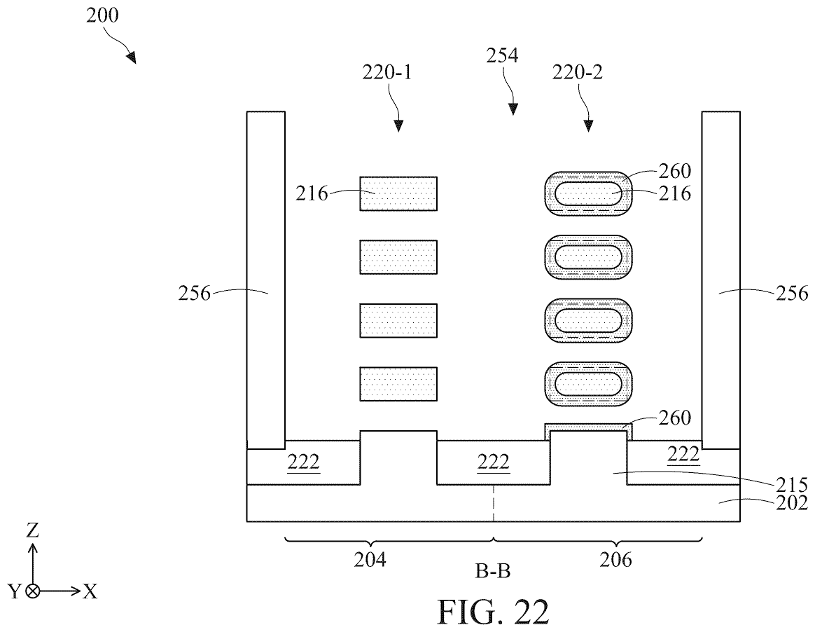

At operation 132, the method 100 removes the patterned mask 258 from the gate trenches 254, as shown in FIG. 22, which is a cross-sectional view along B-B line of the device 200 in FIG. 6. Any suitable removal processes including dry etching, wet etching, and/or reactive ion etching (RIE) may be used.

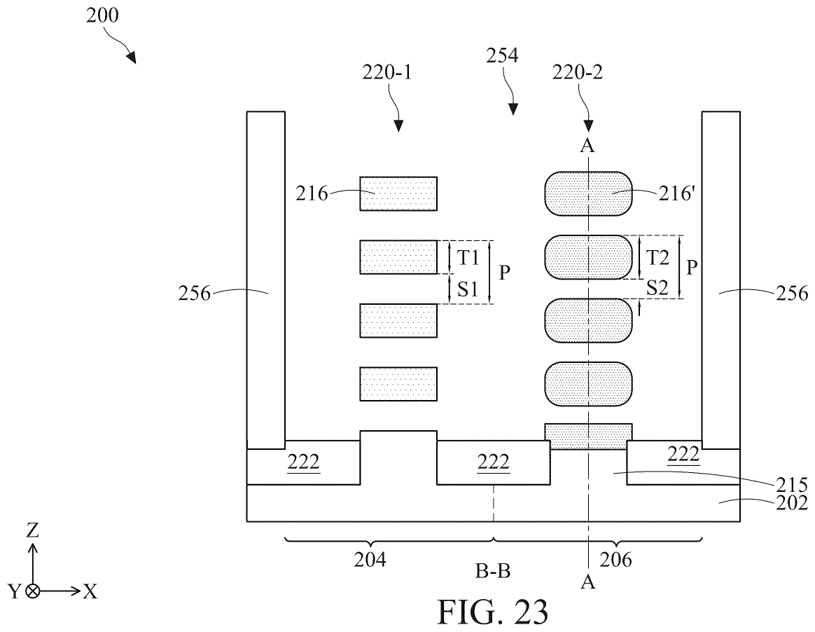

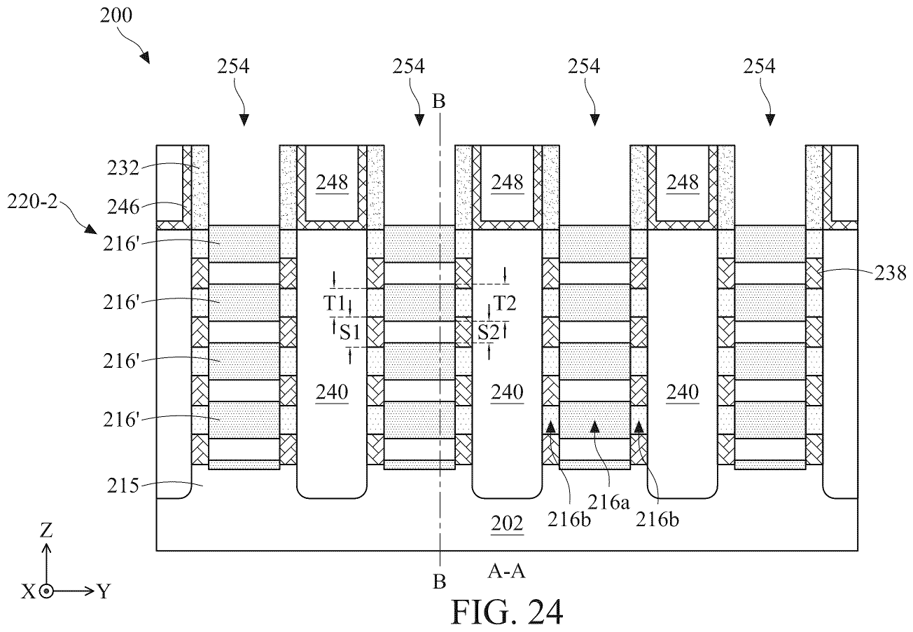

At operation 134, the method 100 performs an anneal process to drive germanium contained in the semiconductor layer 260 into the respective surrounded nanostructures 216 in the fin 220-2. The resultant structure is shown in FIGS. 23 and 24. FIG. 23 is a cross-sectional view along B-B line of the device 200 in FIG. 6 (also B-B line in FIG. 24), and FIG. 24 is a cross-sectional view along A-A line of the device in FIG. 6 (also A-A line in FIG. 23). In some embodiments, the device 200 is exposed to a gas that contains nitrogen (N), phosphorus, or other suitable elements. To avoid oxidation of the semiconductor layer 260 (e.g., silicon germanium), in some embodiments, the gas contains no oxygen content. The conditions of the anneal process are adjusted to control the profile and characteristics of the resulting channel. In an example, the anneal process is performed at temperatures between about 600 degrees Celsius to about 1400 degrees Celsius. The anneal process may be performed for a relatively long period such as 12 seconds to 120 seconds (called “soaking”) or a relatively short period such as hundreds of milliseconds to a few seconds (e.g., 100 milliseconds to 1 seconds) (called “spiking”).

The anneal process causes germanium atoms, and possibly silicon atoms, contained in the semiconductor layer 260 to diffuse or migrate into the respective surrounded nanostructures 216. On the other hand, silicon atoms contained in the semiconductor layers 260 may also diffuse or migrate into the corresponding surrounded nanostructures 216. As a result of the migration of atoms, the semiconductor layer 260 decrease in germanium content, and the respective surrounded nanostructures 216 increase in germanium content. In an embodiment, after the anneal process, the semiconductor layer 260 is Si₁₋ₓGeₓ that includes more than 0% but equal to or less than about 70% (0.1<x≤0.7) Ge in molar ratio. Such a range of Ge is a result of diluting the initial concentration of Ge in the semiconductor layer 260 (e.g. about 10% to about 100%, as described above) and effectively converts the channel region in the PFET region 206 from a first-type (e.g., n-type) to a second-type (e.g., p-type). The semiconductor layer 260 and the respective surrounded nanostructure 216 may effectively combine to form a new suspended channel layer 216′ (or nanostructure 216′), as the material compositions of the semiconductor layer 260 and the respective surrounded nanostructure 216 become the same or similar (e.g., when germanium gets uniformly distributed throughout the channel layer 216′) and the physical interface between the semiconductor layer 260 and the respective surrounded nanostructure 216 becomes hard to discern or indiscernible.

Since the suspended nanostructures 216′ are formed as a combination of corresponding semiconductor layer 260 and nanostructure 216, the suspended nanostructures 216′ in the fin 220-2 may be thicker and wider than the suspended nanostructures 216 in the fin 220-1. In some embodiments, each nanostructure 216′ has a channel thickness (denoted as T2) of about 3.5 to about 10 nm, which is larger than the channel thickness T1 in the NFET region 204, and is spaced apart from adjacent nanosheets for a channel spacing (denoted as S2) of about 4 nm to about 14 nm, which is smaller than the channel spacing S1 in the NFET region 204. The width of the nanostructures 216′ is also wider than the width of the nanostructures 216. The vertical channel pitch P remains the same, as the center-to-center vertical distance between two adjacent nanostructures 216′ does not change. In various embodiments, a ratio of the channel thickness T2 to the channel thickness T1 (T2/T1) ranges from about 1.05 to about 1.3, and a ratio of the channel spacing S2 to the channel spacing S1 (S2/S1) ranges from about 0.75 to about 0.95. These ranges are not trivial nor arbitrary. The extra 5% to about 30% thickness improves hole mobility in the PFET transistors without complicating the manufacturing flow. If the extra thickness is less than about 5%, the performance improvement in the PFET transistors is insignificant; if the extra thickness is larger than 30%, the channel spacing becomes too small and make it difficult for the subsequent deposition of work function metal layer in the gaps between the nanostructures 216′. The material composition difference between the nanostructures 216′ and 216 together with the thickness difference also allows the PFET transistors to achieve a wider threshold voltage (Vt) tuning range, making the to-be-formed CMOS device more suitable for high speed and/or low power applications. Notably, the cross-sections of the nanostructures 216′ and 216 may be different due to the trimming process applied to the PFET region 206. In the depicted embodiment, the cross-section of the nanostructure 216 has a rectangle-shape with substantially right angles, and the cross-section of the nanostructure 216′ has an obround shape or an oval shape with rounded corners.

Also as depicted in FIG. 23, the top portion of the fin-shape base 215 in the PFET region 206 is taller and wider than the fin-shape base 215 in the NFET region 204 due to the extra epitaxial grown semiconductor layer 260 on its top and sidewall surfaces. The top portion of the fin-shape base 215 in the PFET region 206 is also wider than its bottom portion stacked between the STI features 222. As a comparison, the top and bottom portions of the fin-shape base 215 in the NFET region 204 may have substantially the same width. A width of the top portion of the fin-shape base 215 in the PFET region 206 may also be wider than a width of the nanostructures 216′, as the nanostructures 216′ may have more etching loss in the lateral direction during the trimming process. The anneal process also causes germanium atoms to diffuse into the fin-shape base 215. Unlike germanium concentration in the nanostructures 216′ that may get uniformly distributed throughout the nanostructures 216′, the germanium concentration in the fin-shape base 215 in the PFET region 2106 has a gradient in the direction from top to bottom. Germanium atoms may diffuse to an interface below the top surface of the STI features 222.

According to some embodiments disclosed herein, the driven-in germanium atoms get distributed in the suspended nanostructures 216′ in various ways, which may be tailored by controlling the conditions of the anneal process. As shown in FIG. 24, when the semiconductor layer 260 is epitaxially grown, it is attached to the middle sections 216a of the suspended nanostructures. Thus, during the anneal process, germanium atoms in the semiconductor layers 260 may diffuse mostly into the middle sections 216a (and not the end sections 216b) of respective suspended nanostructures. FIG. 25A illustrates an example concentration profile of germanium along the Y-direction. As shown in FIG. 25A, a concentration of germanium in the middle section 216a of each channel layer 216′ is higher than a concentration of the germanium in the two end sections 216b of the channel layer 216′. Any suitable methods of determining concentration may be used (e.g., by determining an average concentration or median concentration). In an embodiment, the concentration of the germanium in the middle section 216a of each channel layer 216′ is substantially uniform, while the concentration of the germanium in the end sections 216b of each channel layer 216′ takes a gradient profile (e.g., gradually decreasing from the high concentration in the middle section 216a until the concentration becomes zero). Note that, due to the spreading nature of germanium migration in the anneal process, the concentration of germanium may start to decrease at points C and C′ shown in FIG. 25A, which may be a few nanometers off from the interface between the middle section 216a and an end section 216c. In some embodiments (for example, when the anneal process has a short duration and/or low temperatures), germanium does not reach far enough under the gate sidewall spacers 232 to reach the S/D regions 240. Instead, the concentration of germanium drops to zero at the points D and D′ shown in FIG. 25A. Thus, at least a portion of the two end sections 216b—which is in direct contact with the gate sidewall spacers 232 and the epitaxial S/D features 240—is substantially devoid of germanium. In an embodiment, the entire end sections 216b of the channel layer 216′ are substantially devoid of germanium.

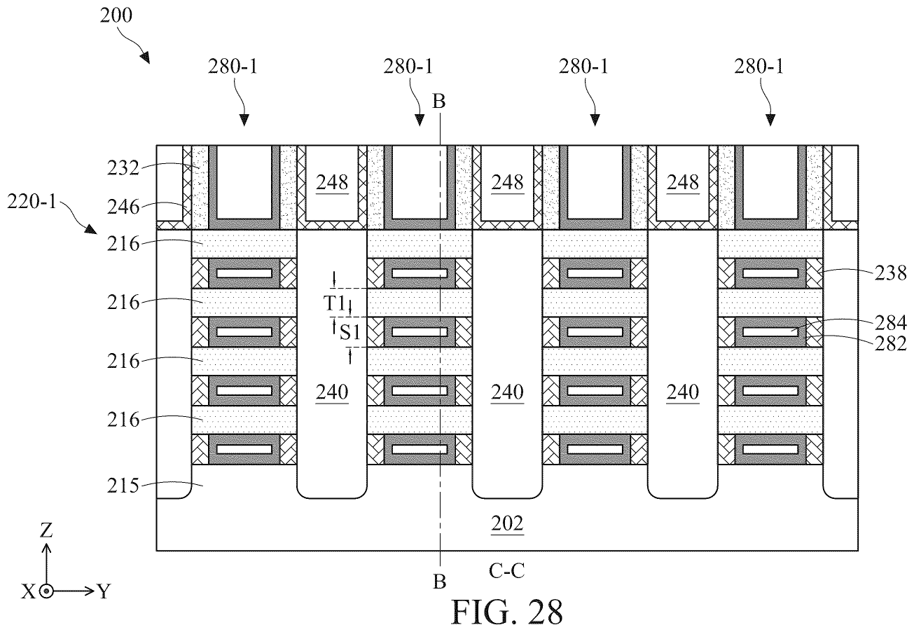

FIG. 25B illustrates some exemplary concentration profiles of germanium in the X-Z plane. As shown in FIG. 28B, a concentration of germanium in a core portion of each channel layer 216′ may be equal to or lower than a concentration of germanium in an edge portion of the channel layer 216′. Different concentration profiles may be realized by controlling various parameters such as the thickness of a semiconductor layer 260, the concentration of germanium in the semiconductor layer 260, and/or conditions of the anneal process. For example, a thicker semiconductor layer 260 supplies more germanium atoms, and a longer anneal process (or performed at higher temperatures) drives germanium further into a core of the channel layer 216′, thereby leading to a more uniform concentration of germanium.

In FIG. 25B, profiles 302, 304, 306 represent three distinctive concentration profiles of germanium in the channel layer 216′ corresponding to different sets of parameters. Profile 302 represents the case where the semiconductor layer 260 contains about 50% to about 60% of germanium, and is annealed at a soaking temperature of about 1250 degrees Celsius to about 1300 degrees Celsius for about 60 seconds to about 100 seconds. A uniform germanium concentration of about 35% to 40% is achieved in both the core portion and the edge portion of the channel layer 216′. In profile 304, the semiconductor layer 312 contains about the same concentration of germanium as in profile 1210, and is annealed at a spiking temperature of about 1100 degrees Celsius to about 1150 degrees Celsius for about 3 seconds to about 5 seconds. The germanium concentration follows a gradient profile that decreases from a maximal concentration of about 30% to about 35% at the edge of the channel layer 216′ to a minimal concentration of about 15% to about 20% at the core of the channel layer 216′. In profile 306, the semiconductor layer 312 contains about 30% to about 40% of germanium, and is annealed at a spiking temperature of about 1050 degrees Celsius to about 1080 degrees Celsius for about 500 milliseconds to about 1 second. The germanium concentration follows a gradient profile that decreases from a maximal concentration of about 20% to about 25% at the edge of the channel layer 216′ and drops to zero before reaching the core of the channel layer 216′. Thus, a center region at the core of the channel layer 216′ may be devoid of germanium. The oval shape 308 represented by dashed lines in FIG. 28B illustrates such an embodiment. The oval shape 308 at the core of the channel layer 216′ represents a silicon rod devoid of germanium. Such a gradient profile is caused by the relatively short duration of the anneal process (e.g., insufficient time for germanium to migrate all the way to the core). Each specific set of parameters leads to a distinctive concentration profile of germanium in the channel layer 216′.

Notably, the introduction of germanium into the suspended channel layers in the PFET region 206 may alternatively be implemented by a doping process. That is, by opting operation 130 with operation 130′, the method 100 (FIG. 1) may dope the nanostructures 216 in the PFET region 206 to derive similar suspended channel layers 216′ as described above. In some embodiments, the nanostructures in both the NFET and PFET regions are in the form of silicon nanosheets with lightly doped germanium, where the germanium concentration is less than about 1×10¹⁷ cm⁻³. After the doping process, the silicon nanosheets in the PFET region 206 have an increased germanium concentration that is more than 50% greater than the germanium concentration in the silicon nanosheets in the NFET region 204. The relationships between channel layer thicknesses and spacings as discussed above and the germanium concentration profiles as illustrated in FIGS. 25A and 25B also apply.

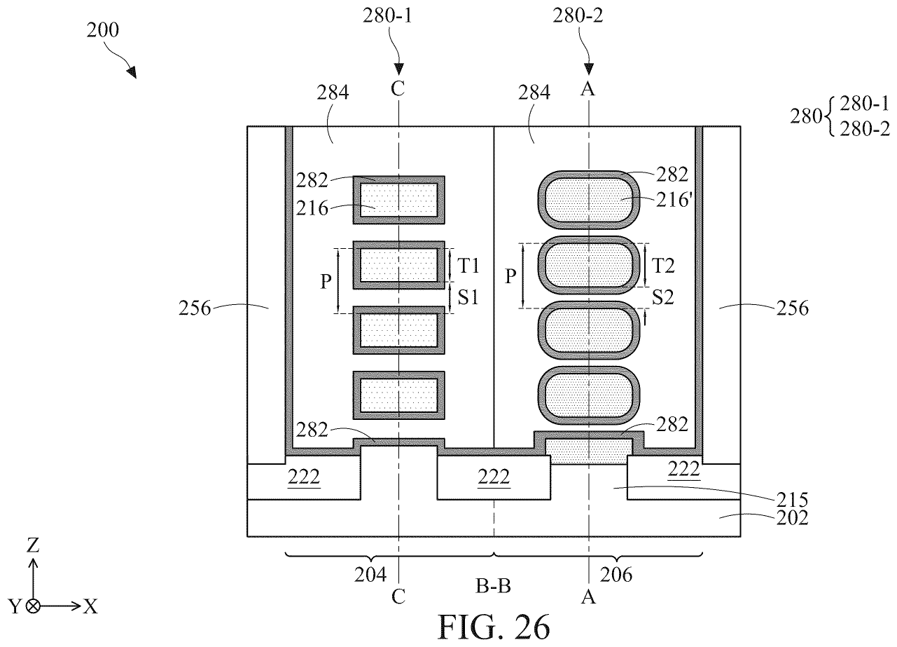

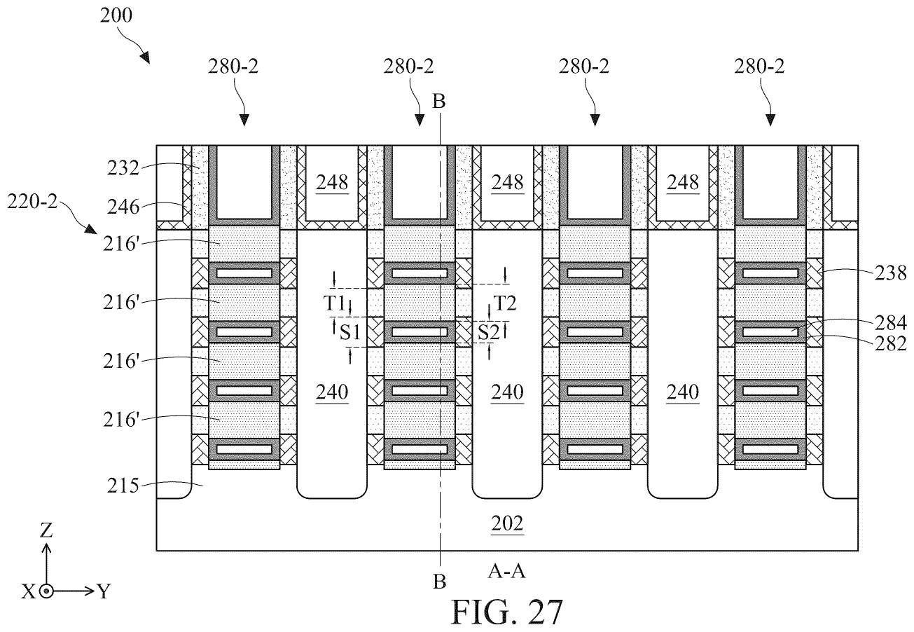

At operation 136, the method 100 (FIG. 1) forms metal gate stacks 280-1 and 280-2 (collectively as metal gate stacks 280) engaging the channel layers 216 in the NFET region 204 and the channel layers 216′ in the PFET region 206, respectively. The resultant structure is shown in FIGS. 26-28. FIG. 26 is a cross-sectional view along B-B line of the device 200 in FIG. 6 (also B-B line in FIGS. 27 and 28), FIG. 27 is a cross-sectional view along A-A line of the device 200 in FIG. 6 (also A-A line in FIG. 23), and FIG. 28 is a cross-sectional view along C-C line of the device 200 in FIG. 26. Referring to FIGS. 26-28 collectively, the metal gate stacks 280-1 and 280-2 fill the gate trenches 254 and wrap around each of the exposed suspended channel layers, such as the nanostructures 216 in the NFET region 204 and the nanostructures 216′ in the PFET region 206, respectively. The metal gate stacks 280-1 and 280-2 have similar structures, but in some embodiments use different metals and/or different thicknesses of layers. The metal gate stacks 280-1 and 280-2 may also be considered as two portions (segments) of one continuous metal gate stack 280 in the CMOS context. In the present embodiment, the metal gate stacks 280 include a gate dielectric layer 282 and a gate electrode 284 over the gate dielectric layer 282. The gate dielectric layer 282 may include one or multiple layers of dielectric materials on interior surfaces of the gate trenches 254 and directly wrapping over each of the channel layers. The gate dielectric layer 282 includes an interfacial layer such as silicon oxide or silicon oxynitride, and is formed by chemical oxidation, thermal oxidation, ALD, CVD, and/or other suitable methods. In some embodiments, the gate dielectric layer also includes a high-k dielectric layer such as hafnium oxide, zirconium oxide, lanthanum oxide, titanium oxide, yttrium oxide, strontium titanate, other suitable metal-oxides, or combinations thereof; and is formed by ALD and/or other suitable methods. The gate electrode 284 includes a work function metal layer and a metal fill layer over the work function layer. The work function metal layer is a p-type work function metal layer in the PFET region 206 or an n-type work function metal layer in the NFET region 204. The p-type work function metal layer comprises a metal selected from, but not limited to, the group of titanium nitride, tantalum nitride, ruthenium, molybdenum, tungsten, platinum, or combinations thereof. The n-type work function metal layer comprises a metal selected from, but not limited to, the group of titanium, aluminum, tantalum carbide, tantalum carbide nitride, tantalum silicon nitride, or combinations thereof. In some embodiments, the p-type or n-type work function metal layer includes a plurality of layers deposited by CVD, PVD, and/or other suitable process. The metal fill layer includes aluminum, tungsten, cobalt, copper, and/or other suitable materials, and is formed by CVD, PVD, plating, and/or other suitable processes. In some embodiments, the metal gate stacks 280 wrap around the vertically-stacked horizontally-oriented channel layers. Hence, the device 200 is a vertically-stacked horizontal gate-all-around (HGAA) device. In an embodiment, after the metal gate stacks 280 are deposited, a CMP process is performed to planarize a top surface of the device 200. Notably, in FIGS. 27 and 28, as discussed above S/D regions of the n-type GAA transistors and the p-type GAA transistors may employ either one of the configurations of S/D regions as depicted in FIGS. 12, 13, and 14 or a combination thereof.

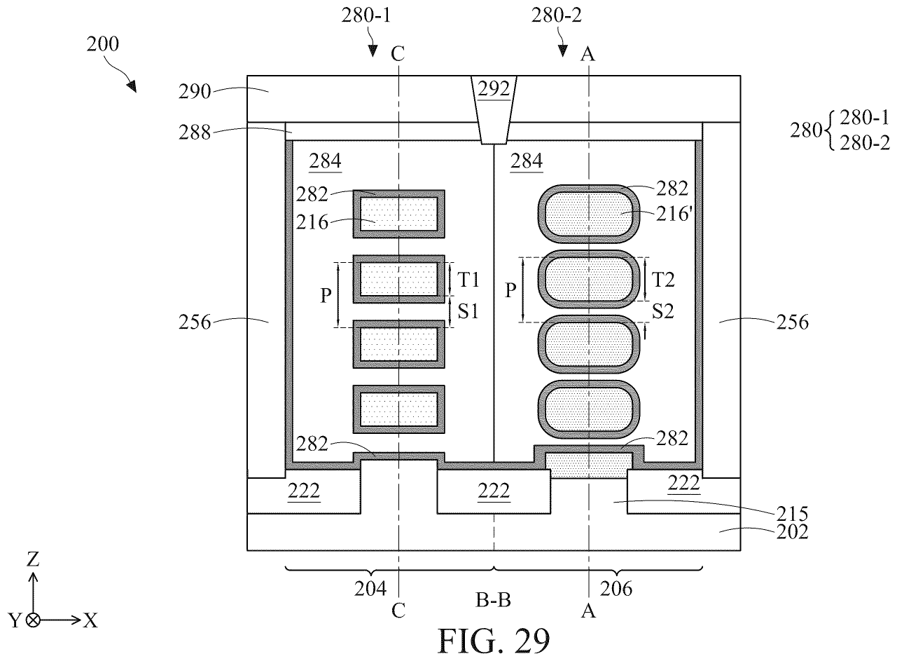

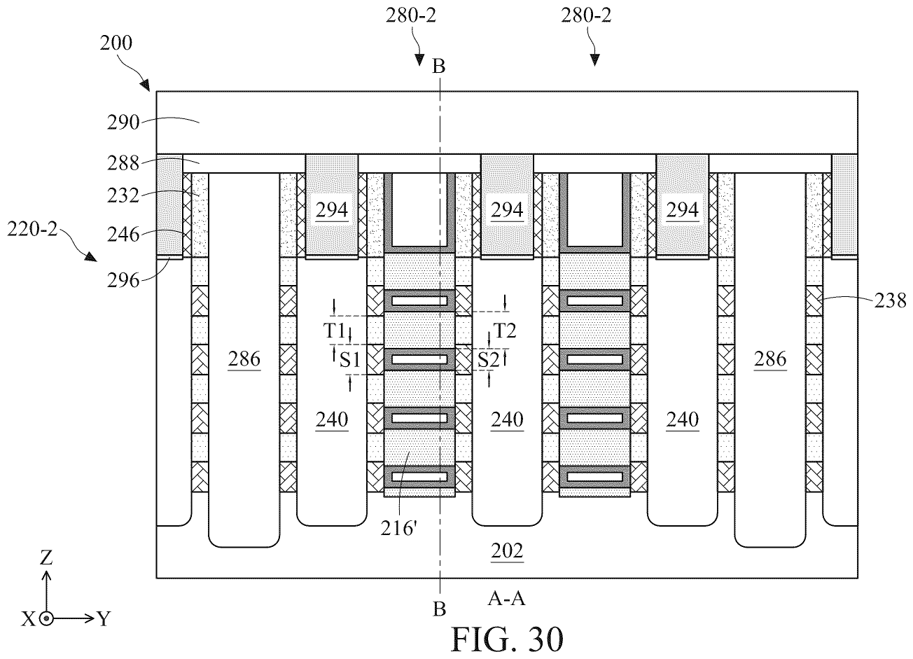

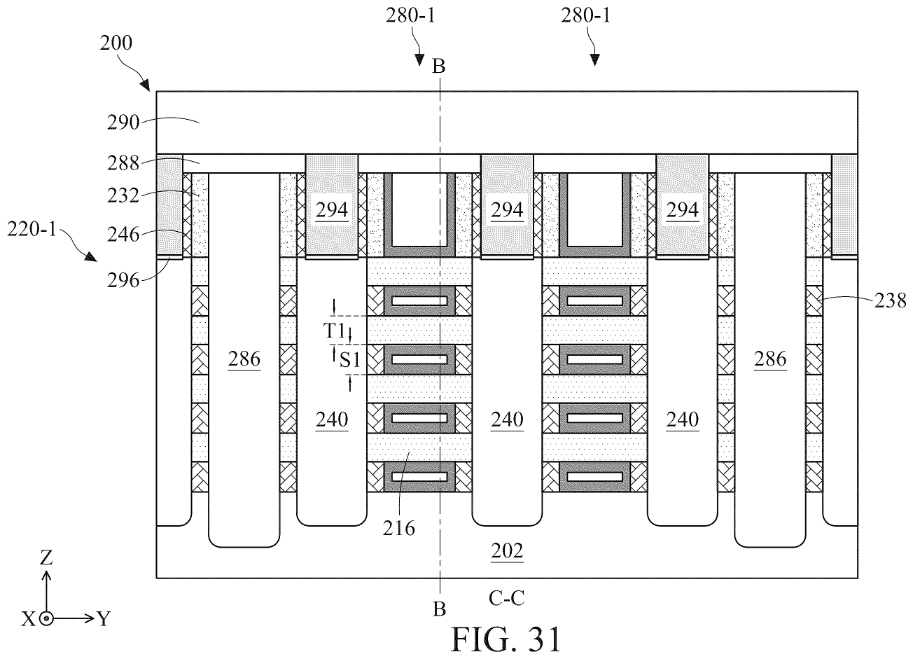

Further processes may be performed to complete the fabrication of the device 200. The resultant structure after some exemplary further processes is shown in FIGS. 29, 30, 31, and 32. FIG. 32 is a top view of the device 200, FIG. 29 is a cross-sectional view along B-B line of the device 200 in FIG. 32, FIG. 30 is a cross-sectional view along A-A line of the device 200 in FIG. 32, and FIG. 31 is a cross-sectional view along C-C line of the device 200 in FIG. 32. Referring to FIGS. 29-32 collectively, the method may continue to recess the metal gate stacks 280 in an etching process such as dry etching, wet etching, RIE, and/or other etching methods, and replace two metal gate stacks 280 at the location of the sacrificial gate structures 224-1 and 224-4 with two dielectric isolation features 286 such as SiO2, silicon oxynitride, FSG, a low-k dielectric, combinations thereof, and/or other suitable dielectric materials. The replacement of the metal gate stacks 280 is also referred to a cut-poly (CPO) process, and the dielectric isolation features 286 is also referred to as CPO features. The CPO features 286 may extend into the substrate 202 such as below the bottom surface of the epitaxial S/D features 240. The method may continue to form a capping layer 288 over the remaining metal gate stacks 280 and the CPO features 286 and a second ILD layer 290 over the capping layer 288. The capping layer 288 may include a semiconductor material such as silicon, or a dielectric material such as silicon oxide, silicon nitride, silicon carbide, silicon oxynitride, combinations thereof, or another suitable material. The second ILD layer 290 may include the same or a different material from the ILD layer 248, such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The method may continue to form contact openings and contact plugs in the contact openings, such as gate contact plugs 292, source/drain contact plugs 294, and optional silicide features 296 between the source/drain contact plugs 294 and epitaxial S/D features 240. Each contact plug may include a conductive barrier layer and a bulk metal layer. The conductive barrier layer may include titanium (Ti), tantalum (Ta), tungsten (W), cobalt (Co), ruthenium (Ru), or a conductive nitride such as titanium nitride (TiN), titanium aluminum nitride (TiAlN), tungsten nitride (WN), tantalum nitride (TaN), or combinations thereof, and may be formed by CVD, PVD, ALD, and/or other suitable processes. The bulk metal layer may include tungsten (W), cobalt (Co), molybdenum (Mo), ruthenium (Ru), nickel (Ni), copper (Cu), or other metals, and may be formed by CVD, PVD, ALD, plating, or other suitable processes.

The method may continue to form various other contact plugs, vias (such as source/drain contact vias 298 as shown in FIG. 32), wires, and multilayer interconnect features (e.g., metal layers and interlayer dielectrics) over the device 200, configured to connect the various features to form a functional circuit that may include one or more multi-gate transistors, such as GAA transistors T1, T2, T3, and T4 as shown in FIG. 32. The n-type GAA transistor T1 and the p-type GAA transistor T2 form dual transistors in a first CMOS device, the n-type GAA transistor T3 and the p-type GAA transistor T4 form dual transistors in a second CMOS device. The n-type and p-type transistors in the pair have different thicknesses and material compositions in the channel layers, which allows device performances of transistors of opposite conductivity types to be optimized collectively. The first and second CMOS devices are stacked between two CPO features 286 along the Y-direction and stacked between two gate end dielectric features 256 along the X-direction. The CPO features 286 and the gate end dielectric features 256 isolate the first and second CMOS devices from other adjacent devices and reduce interference therefrom. The structure as depicted in FIG. 32 may be implemented in various types of circuits, such as in logic circuits, memory circuits (e.g., such as SRAM, etc.), and/or other types of circuits. FIG. 33 illustrates such an implementation.

The reference is now made to FIG. 33, which illustrates a layout 400 of a memory macro which includes a memory array 402 and a logic circuit (or referred to as input/output (I/O) circuit) 404 that includes the CMOS devices as depicted in FIG. 32 as some of the logic cells. For simplicity, only first two rows (Row 1-2) of the memory array 402 and a portion of the logic circuit 404 are shown.

The SRAM cells in the memory array 402 and the logic cells in the logic circuit 404 include active regions (such as in the form of stacked channel layers 216 and 216′) arranged along the X-direction and oriented lengthwise in the Y-direction. The memory macro further includes metal gate stacks 280 arranged along the Y-direction and extending lengthwise in the X-direction. In the illustrated embodiment, the metal gate stacks 280 are evenly distributed along the Y-direction with a uniform distance between two adjacent gate structures 280. The uniform distance is denoted as a gate pitch or a poly pitch (“PP”). The SRAM cell width W can also be measured by the number of poly pitches. In the illustrated embodiment, the SRAM cell width W is two times a poly pitch. A width of the memory array 402 along the Y-direction can also be measured by the number of poly pitches. Since each SRAM cell has a width W of two times a poly pitch, for having a number of N SRAM cells in a row (also as N columns in the memory array 402), the memory array 402 has a width of 2*N poly pitches.

The metal gate stacks 280 intersect the active regions in forming transistors. Transistors formed at the intersections of the active regions and the metal gate stacks 280 within the memory array 402 are devoted to form SRAM cells. The transistors formed at the intersections of the active regions and the metal gate stacks 280 within the logic circuit 404 are devoted to form logic cells. In the illustrated embodiment, the transistors in the SRAM array 402 form a plurality of SRAM cells, such as SRAM cells BC₁₁, BC₁₂, BC₂₁, BC₂₂ (collectively, SRAM cells BC). Each SRAM cell BC in the array may include six transistors: a pass-gate transistor PG-1, a pass-gate transistor PG-2, a pull-up transistor PU-1, a pull-up transistor PU-2, a pull-down transistor PD-1, and a pull-down transistor PD-2. In some embodiments, the pull-up transistors PU-1, PU-2 are configured as p-type GAA transistors, and the pull-down transistors PD-1, PD-2, pass-gate transistors PG-1, PG-2 are configured as n-type GAA transistors.

Some active regions extend through multiple SRAM cells in a row. For example, the active region for the transistors PD-1, PG-1 in the SRAM cell BC₁₁ extends through the SRAM cell BC₁₂ as the active region for its transistors PG-1, PD-1 and further through the other SRAM cells BC in the Row 1; the active region for the transistors PG-2, PD-2 in the SRAM cell BC₁₁ extends through the SRAM cell BC₁₂ as the active region for its transistors PD-2, PG-2 and further through the other SRAM cells BC in the Row 1; and the active region for the transistors PU-2 in the SRAM cell BC₁₁ extends into the SRAM cell BC₁₂ as the active region for its transistors PU-2. The active regions in the SRAM cells BC₂₁, BC₂₂ are similarly arranged.

The transistors (such as transistors T1, T2, T3, T4) in the logic region 304 form a plurality of logic cells. The logic cells may be standard cells, such as inventor (INV), AND, OR, NAND, NOR, Flip-flip, SCAN and so on. The logic cells implement various logic functions to the SRAM cells BC. The logic functions of the logic cells include, for example, write and/or read decoding, word line selecting, bit line selecting, data driving and memory self-testing. As depicted, each logic cell has a logic cell height CH, which is half of the SRAM cell height H. Therefore, two logic cells have a boundary with opposing edges aligned with opposing edges of the boundary of one SRAM cell with the edges spaced in the Y-direction and each edge extending in the X-direction.

Between the opposing boundary lines of the SRAM cells in the memory array 402 and the logic circuit 404 is an active region transition region 406, or simply as the transition region 406. Inside the transition region 406, the active regions extending from the edge column of the SRAM cells meet the active regions extending from the edge column of the logic cells. Since the abutting active regions may have different widths, a jog is created at where the active regions meet. A jog refers to a junction where two segments of different widths meet each other.

As depicted in the layout 400, the transition region 406 may have a span of one poly pitch between the opposing boundary lines of the SRAM cells and the logic cells along the Y-direction. In the transition region 406, a CPO feature (or isolation feature) 286 is oriented lengthwise in the X-direction and provides isolation between the active regions in the memory array 402 and the logic circuit 404. The CPO feature 286 overlaps with the jogs. In the exemplary layout 400, the CPO features of the logic cells in the same column adjoin and form a continuous CPO feature 286 that continuously extends along the boundary lines of the SRAM cells and the logic cells in the X-direction. In other words, the CPO feature 286 may be taller than the SRAM cell height H. As discussed above, the CPO feature 286 is formed by replacing the previously-formed metal gate stacks, the CPO feature 286 inherits the arrangement of the metal gate stacks 280. That is, the CPO feature 286 may have the same width as the metal gate stacks 280 and the same pitch as the metal gate stacks 280. The CPO features 286 (together with the gate end dielectric features 256 as shown in FIG. 32) improve signal integrity of the CMOS devices in the logic circuit 404 from interference from the SRAM cells BC in the memory array 402.

Although not intended to be limiting, one or more embodiments of the present disclosure provide many benefits to a semiconductor device and a formation process thereof. For example, embodiments of the present disclosure form dual channel GAA FET devices on multiple fins. According to some embodiments, after growing a stack of alternating n-type and p-type semiconductor layers, a method directly patterns the stack to create first and second fins, and then removes the p-type semiconductor layers to create suspended p-type nanostructures on both fins. The method then converts the suspended p-type nanostructures of the second fin to p-type nanostructures by growing thin p-type semiconductor (e.g., germanium or silicon germanium) layers that wrap around the suspended p-type nanostructures and then performing an anneal process to drive germanium atoms into the suspended p-type nanostructures. As a result, dual channel GAA FETs are achieved with a simplified fabrication process. In some embodiments, the channels only have germanium at a gate contact region (not end sections under gate spacers). Further, embodiments of the present disclosure may be integrated into existing CMOS fabrication flow, providing for improved process window.

In one example aspect, the present disclosure provides a method of forming a semiconductor device. The method includes providing a substrate having a plurality of first semiconductor layers and a plurality of second semiconductor layers disposed over the substrate. The first and second semiconductor layers have different material compositions and are alternatingly disposed with respect to each other in a vertical direction. Each of the first and second semiconductor layers extends over first and second regions of the substrate. The method also includes patterning the first semiconductor layers and the second semiconductor layers to form a first fin in the first region and a second fin in the second region, removing the first semiconductor layers from the first and second fins such that a first portion of the patterned second semiconductor layers becomes first suspended nanostructures in the first fin and that a second portion of the patterned second semiconductor layers becomes second suspended nanostructures in the second fin, forming a third semiconductor layer wrapping around each of the second suspended nanostructures in the second fin, the second and third semiconductor layers having different material compositions, performing an anneal process to incorporate materials contained in the third semiconductor layer into the second suspended nanostructures in the second fin, such that a thickness of the second suspended nanostructures is increased to be larger than a thickness of the first suspended nanostructures, and forming a gate stack wrapping around each of the first and second suspended nanostructures. In some embodiments, after the anneal process, the thickness of the second suspended nanostructures is increased to be at least 5% larger than the thickness of the first suspended nanostructures. In some embodiments, after the anneal process, the thickness of the second suspended nanostructure is less than about 1.3 times the thickness of the first suspended nanostructures. In some embodiments, the method also includes prior to the forming of the third semiconductor layer, trimming the second suspended nanostructures to reduce the thickness of the second suspended nanostructure to be less than the thickness of the first suspended nanostructures. In some embodiments, after the anneal process the materials contained in the third semiconductor layer are distributed uniformly in middle sections of the second suspended nanostructures and are distributed following a gradient profile in end sections of the second suspended nanostructures. In some embodiments, the first suspended nanostructures in the first fin are for providing a channel region in an n-type transistor, and the second suspended nanostructures in the second fin are for providing a channel region in a p-type transistor as a result of the materials incorporated into the second suspended nanostructures. In some embodiments, before the anneal process the first and second suspended nanostructures consist essentially of silicon, and after the anneal process at least an outer portion of the second suspended nanostructures consists silicon germanium. In some embodiments, before the anneal process the first and second suspended nanostructures consist essentially of silicon, and after the anneal process the second suspended nanostructure consists a silicon core wrapped around by an outer silicon germanium layer. In some embodiments, after the removing of the first semiconductor layers the first fin includes a first fin-shape base directly under the first suspended nanostructures, and the second fin includes a second fin-shape base directly under the second suspended nanostructures, and after the anneal process a top portion of the second fin-shape base is taller and wider than a top portion of the first fin-shape base. In some embodiments, the method also includes forming a first epitaxial feature abutting the first suspended nanostructures, forming a first dielectric film directly under the first epitaxial feature, the first dielectric film separating the first epitaxial feature form physically contacting the substrate, forming a second epitaxial feature abutting the second suspended nanostructures, and forming a second dielectric film directly under the second epitaxial feature, the second dielectric film separating the second epitaxial feature form physically contacting the substrate.

In another example aspect, the present disclosure provides a method. The method includes forming a sacrificial gate structure over channel regions of first and second fins, removing the sacrificial gate structure to expose the channel regions of the first and second fins, removing sacrificial layers from the first and second fins to form a plurality of first suspended layers in the first fin and a plurality of second suspended layers in the second fin, the first and second suspended layers including a same first semiconductor material, forming a mask covering the first suspended layers, while the first suspended layers are covered by the mask, performing a doping process to introduce a second semiconductor material that differs from the first semiconductor material into the second suspended layers, removing the mask, after the removing of the mask, performing an anneal process to adjust a distribution of the second semiconductor material in the second suspended layers, and forming a metal gate stack wrapping around each of the first and second suspended layers. In some embodiments, the first semiconductor material is silicon, and the second semiconductor material is germanium. In some embodiments, after the anneal process a ratio of a thickness of the second suspended layers to a thickness of the first suspended layers ranges between about 1.05 and about 1.3. In some embodiments, the first suspended layers also include the second semiconductor material, and wherein a concentration of the second semiconductor material in the second suspended layers is at least 50% more than a concentration of the second semiconductor material in the first suspended layers. In some embodiments, the concentration of the second semiconductor material in the first suspended layers is less than about 1×10¹⁷ cm⁻³. In some embodiments, the method also includes prior to the doping process, trimming the second suspended layers to reduce a thickness of the second suspended layers to be less than a thickness of the first suspended layers. In some embodiments, the method also includes forming a first epitaxial feature abutting the first suspended layers, forming a first dielectric layer directly under the first epitaxial feature, forming a second epitaxial feature abutting the second suspended layers, and forming a second dielectric layer directly under the second epitaxial feature.

In yet another example aspect, the present disclosure provides a semiconductor structure. The semiconductor structure includes a substrate, a first nanostructure suspended above the substrate and extending lengthwise along a first direction, a second nanostructure suspended above the substrate and extending lengthwise along the first direction, and a gate stack engaging the first nanostructure to form an n-type transistor and engaging the second nanostructure to form a p-type transistor. In a top view of the semiconductor structure the gate stack extends lengthwise along a second direction perpendicular to the first direction. The semiconductor structure also includes gate spacers disposed on sidewalls of the gate stack. In a first cross-sectional plane cut along the second direction and perpendicular to a top surface of the substrate, the gate stack wraps around the first and second nanostructures, and the second nanostructure is thicker than the first nanostructure and includes a material composition different from the first nanostructure. In some embodiments, the second nanostructure is thicker than the first nanostructure for at least 5%. In some embodiments, in a second cross-sectional plane cut along the first direction and perpendicular to the top surface of the substrate, the second nanostructure has a middle portion in physical contact with the gate stack and an end portion in physical contact with the gate spacers, and the middle portion is thicker than the end portion.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, comprising:
providing a substrate having a plurality of first semiconductor layers and a plurality of second semiconductor layers disposed over the substrate, wherein the first and second semiconductor layers have different material compositions and are alternatingly disposed with respect to each other in a vertical direction, wherein each of the first and second semiconductor layers extends over first and second regions of the substrate;
patterning the first semiconductor layers and the second semiconductor layers to form a first fin in the first region and a second fin in the second region;
removing the first semiconductor layers from the first and second fins such that a first portion of the patterned second semiconductor layers becomes first suspended nanostructures in the first fin and that a second portion of the patterned second semiconductor layers becomes second suspended nanostructures in the second fin;
forming a third semiconductor layer wrapping around each of the second suspended nanostructures in the second fin, wherein the second and third semiconductor layers have different material compositions;
performing an anneal process to incorporate materials contained in the third semiconductor layer into the second suspended nanostructures in the second fin, such that a thickness of the second suspended nanostructures is increased to be larger than a thickness of the first suspended nanostructures; and
forming a gate stack wrapping around each of the first and second suspended nanostructures.

2. The method of claim 1, wherein after the anneal process, the thickness of the second suspended nanostructures is increased to be at least 5% larger than the thickness of the first suspended nanostructures.

3. The method of claim 1, wherein after the anneal process, the thickness of the second suspended nanostructure is less than about 1.3 times the thickness of the first suspended nanostructures.

4. The method of claim 1, further comprising:
prior to the forming of the third semiconductor layer, trimming the second suspended nanostructures to reduce the thickness of the second suspended nanostructure to be less than the thickness of the first suspended nanostructures.

5. The method of claim 1, wherein after the anneal process the materials contained in the third semiconductor layer are distributed uniformly in middle sections of the second suspended nanostructures and are distributed following a gradient profile in end sections of the second suspended nanostructures.

6. The method of claim 1, wherein the first suspended nanostructures in the first fin are for providing a channel region in an n-type transistor, and wherein the second suspended nanostructures in the second fin are for providing a channel region in a p-type transistor as a result of the materials incorporated into the second suspended nanostructures.

7. The method of claim 1, wherein before the anneal process the first and second suspended nanostructures consist essentially of silicon, and wherein after the anneal process at least an outer portion of the second suspended nanostructures consists silicon germanium.

8. The method of claim 1, wherein before the anneal process the first and second suspended nanostructures consist essentially of silicon, and wherein after the anneal process the second suspended nanostructure consists a silicon core wrapped around by an outer silicon germanium layer.

9. The method of claim 1, wherein after the removing of the first semiconductor layers the first fin includes a first fin-shape base directly under the first suspended nanostructures, and the second fin includes a second fin-shape base directly under the second suspended nanostructures,
and wherein after the anneal process a top portion of the second fin-shape base is taller and wider than a top portion of the first fin-shape base.

10. The method of claim 1, further comprising:
forming a first epitaxial feature abutting the first suspended nanostructures;
forming a first dielectric film directly under the first epitaxial feature, wherein the first dielectric film separates the first epitaxial feature form physically contacting the substrate;
forming a second epitaxial feature abutting the second suspended nanostructures; and
forming a second dielectric film directly under the second epitaxial feature, wherein the second dielectric film separates the second epitaxial feature form physically contacting the substrate.

11. A method, comprising:
forming a sacrificial gate structure over channel regions of first and second fins;
removing the sacrificial gate structure to expose the channel regions of the first and second fins;
removing sacrificial layers from the first and second fins to form a plurality of first suspended layers in the first fin and a plurality of second suspended layers in the second fin, wherein the first and second suspended layers include a same first semiconductor material;
forming a mask covering the first suspended layers;
while the first suspended layers are covered by the mask, performing a doping process to introduce a second semiconductor material that differs from the first semiconductor material into the second suspended layers;
removing the mask;
after the removing of the mask, performing an anneal process to adjust a distribution of the second semiconductor material in the second suspended layers; and
forming a metal gate stack wrapping around each of the first and second suspended layers.

12. The method of claim 11, wherein the first semiconductor material is silicon, and the second semiconductor material is germanium.

13. The method of claim 11, wherein after the anneal process a ratio of a thickness of the second suspended layers to a thickness of the first suspended layers ranges between about 1.05 and about 1.3.

14. The method of claim 11, wherein the first suspended layers also include the second semiconductor material, and wherein a concentration of the second semiconductor material in the second suspended layers is at least 50% more than a concentration of the second semiconductor material in the first suspended layers.

15. The method of claim 14, wherein the concentration of the second semiconductor material in the first suspended layers is less than about 1×10¹⁷ cm⁻³.

16. The method of claim 11, further comprising:
prior to the doping process, trimming the second suspended layers to reduce a thickness of the second suspended layers to be less than a thickness of the first suspended layers.

17. The method of claim 11, further comprising:
forming a first epitaxial feature abutting the first suspended layers;
forming a first dielectric layer directly under the first epitaxial feature;
forming a second epitaxial feature abutting the second suspended layers; and
forming a second dielectric layer directly under the second epitaxial feature.

18. A semiconductor structure, comprising:
a substrate;
a first nanostructure suspended above the substrate and extending lengthwise along a first direction;
a second nanostructure suspended above the substrate and extending lengthwise along the first direction;
a gate stack engaging the first nanostructure to form an n-type transistor and engaging the second nanostructure to form a p-type transistor, wherein in a top view of the semiconductor structure the gate stack extends lengthwise along a second direction perpendicular to the first direction; and
gate spacers disposed on sidewalls of the gate stack,
wherein in a first cross-sectional plane cut along the second direction and perpendicular to a top surface of the substrate, the gate stack wraps around the first and second nanostructures, and the second nanostructure is thicker than the first nanostructure and includes a material composition different from the first nanostructure.

19. The semiconductor structure of claim 18, wherein the second nanostructure is thicker than the first nanostructure for at least 5%.

20. The semiconductor structure of claim 18, wherein in a second cross-sectional plane cut along the first direction and perpendicular to the top surface of the substrate, the second nanostructure has a middle portion in physical contact with the gate stack and an end portion in physical contact with the gate spacers, and the middle portion is thicker than the end portion.
